(19) United States
(12) Patent Application Publication
(10) Pub. No.: US 2014/0326287 A1
(43) Pub. Date: Nov. 6, 2014

(54) WEARABLE THERMOELECTRIC GENERATOR ASSEMBLY AND METHOD OF MANUFACTURING SAME

(71) Applicant: Perpetua Power Source Technologies, Inc., Corvallis, OR (US)

(72) Inventors: Gerald S. WIANT, Eugene, OR (US); Marcus S. WARD, Salem, OR (US); Ingo STARK, Corvallis, OR (US); James R. TEETER, Portland, OR (US); Gabriel D. AHSELN, Corvallis, OR (US); Ryan J. HOFMEISTER, Portland, OR (US); Mark J. HAUCK, Corvallis, OR (US)

(73) Assignee: Perpetua Power Source Technologies, Inc., Corvallis, OR (US)

(21) Appl. No.: 14/267,802

(22) Filed: May 1, 2014

Related U.S. Application Data
(60) Provisional application No. 61/818,782, filed on May 2, 2013.

(51) Int. Cl. H01L 35/32; H01L 35/34

(52) U.S. Cl. CPC H01L 35/32; H01L 35/34
USPC 136/205; 438/55

(57) ABSTRACT

A thermoelectric generator module for a wearable thermoelectric generator assembly may include a top heat coupling plate and a bottom heat coupling plate each having a head formed on an outer surface of the heat coupling plate and thermally conductive strips formed on an inner surface. At least one thermoelectric foil may be interposed between the top and bottom heat coupling plate. A perimeter band may circumscribe the perimeter edges of the top and bottom heat coupling plate and encapsulate the thermoelectric foil. The head of at least one of the top and bottom heat coupling plate may protrude beyond upper and/or lower surfaces of the perimeter band.

### CROSS-REFERENCE TO RELATED APPLICATIONS

This application claim priority to U.S. Provisional Application Ser. No. 61/818,782 entitled WEARABLE THERMOELECTRIC GENERATOR ASSEMBLY AND METHOD OF MANUFACTURING SAME, filed on May 2, 2013, the entire contents of which is incorporated by reference herein.

### FIELD

The present disclosure pertains generally to thermoelectric devices and, more particularly, to a thermoelectric generator module for a wearable thermoelectric generator assembly.

### BACKGROUND

The increasing trend toward miniaturization of microelectronic devices has driven the development of miniaturized power supplies. Batteries and solar cells are traditional power sources for such microelectronic devices. However, the power that is supplied by batteries dissipates over time requiring that the batteries be periodically replaced. Solar cells, although having an effectively unlimited useful life, may only provide a transient source of power as sunlight or light from other sources may not always be available. Furthermore, solar cells require periodic cleaning of their exterior surfaces in order to maintain efficiency of energy conversion.

Thermoelectric generators are self-sufficient energy sources that convert thermal energy into electrical energy under the Seebeck effect. The Seebeck effect is a phenomenon whereby heat differences may be converted into electricity due in large part to charge carrier diffusion in a conductor. Electrical power may be generated under the Seebeck effect by utilizing thermocouples which are each comprised of a pair of dissimilar metals (n-type and p-type) joined at one end. N-type and p-type, respectively, refers to the negative and positive types of charge carriers within the material.

The temperature gradient that exists between the ends of the thermocouple may be artificially applied or the temperature gradient may be natural, occurring as waste heat such as heat that is constantly rejected by the human body. In a wristwatch, one side is exposed to air at ambient temperature while the opposite side is exposed to the higher temperature of the wearer's skin. Thus, a small temperature gradient is typically present across the thickness of the wristwatch. In this same regard, a thermoelectric generator may be placed in contact with a person's skin to take advantage of the temperature gradient and generate a supply of power to operate an electronic device, sensor, or to be used for other purposes. Advantageously, many microelectronic devices require only a small amount of power and are therefore compatible for powering by a thermoelectric generator.

Thermoelectric generators assemblies that are worn on the human body must be relatively robust such that the thermoelectric generator module may power a microelectronic device during various activities of the wearer. For example, a thermoelectric generator module must be capable of absorbing mechanical forces that may be imposed on the thermoelectric generator module if the thermoelectric generator module is bumped against a hard surface. In this regard, the impact of a thermoelectric generator module against a hard surface may impose excessive compressive forces, tensile forces, and shear forces on the thermoelectric generator module. Such forces may compromise the integrity of the electrical connections and/or thermal paths within the thermoelectric generator module.

As can be seen, there exists a need in the art for a thermoelectric generator module for a wearable thermoelectric generator assembly that is capable of handling compressive forces, tensile forces, and shear forces that may be imposed on the thermoelectric generator module without a loss of functionality of the thermoelectric generator module.

### SUMMARY

The present disclosure specifically addresses and alleviates the above-referenced deficiencies associated with wearable thermoelectric generator assemblies. The disclosure provides a thermoelectric generator module for a wearable thermoelectric generator assembly and may include a top heat coupling plate and a bottom heat coupling plate each having a head formed an outer surface of the heat coupling plate and thermally conductive strips formed on an inner surface of the heat coupling plate. At least one thermoelectric foil may be interposed between the top and bottom heat coupling plate. A perimeter band may circumscribe the perimeter edges of the top and bottom heat coupling plate and encapsulate the thermoelectric foil. The head of at least one of the top and bottom heat coupling plates may protrude beyond upper and/or lower surfaces of the perimeter band.

In a further embodiment, the thermoelectric generator module may include a top and bottom heat coupling plate, and a thermoelectric foil interposed between the top and bottom heat coupling plate. The thermoelectric foil may include a substrate having a plurality of thermoelectric legs formed in at least one row on the substrate and electrically connected in series. An end of the thermoelectric legs in one row may be aligned with the thermally conductive strips of the top heat coupling plate, and an opposite end of the thermoelectric legs in the row may be aligned with the thermally conductive strips of the bottom heat coupling plate such that a heat gradient across the top and bottom heat coupling plate causes heat to flow lengthwise through the thermoelectric legs and electrical current to flow in series through the thermoelectric legs. A perimeter band may circumscribe the top and bottom heat coupling plate and encapsulate the thermoelectric foil. The perimeter band may include a pair of side closeouts and a pair of inserts respectively mounted on opposing sides and ends of the top and bottom heat coupling plate. The head of at least one of the top and bottom heat coupling plates may protrude beyond the upper and/or lower surfaces of the side closeouts and inserts.

Also disclosed is a method of manufacturing a wearable thermoelectric generator assembly. The method may include assembling a top and bottom heat coupling plate to opposite sides of a thermoelectric foil having a plurality of thermoelectric legs each having opposing leg ends. The method may include aligning the leg ends on one side of a row of thermoelectric legs with the thermally conductive strips of the top heat coupling plate, and aligning the leg ends on an opposite side of the row with the thermally conductive strips of the bottom heat coupling plate. The method may additionally include installing a perimeter band around perimeter edges of the top and bottom heat coupling plate to encapsulate the thermoelectric foil. The head of at least one of the top and bottom heat coupling plate may protrude beyond upper and/or lower surfaces of the perimeter band.

The features, functions and advantages that have been discussed can be achieved independently in various embodiments of the present disclosure or may be combined in yet other embodiments, further details of which can be seen with reference to the following description and drawings below.

### BRIEF DESCRIPTION OF THE DRAWINGS

These as well as other features of the present disclosure will become more apparent upon reference to the drawings wherein:

FIG. 1 is a perspective view of an embodiment of a thermoelectric generator module as may be mounted in a wearable thermoelectric generator assembly;

FIG. 2 is a top view of the thermoelectric generator module of FIG. 1;

FIG. 3 is a side view of the thermoelectric generator module of FIG. 1;

FIG. 4 is an exploded perspective view of the thermoelectric generator module of FIG. 1;

FIG. 5 is a perspective cross-sectional view of the thermoelectric generator module taken along line 5 of FIG. 1;

FIG. 6 is a side sectional view of the thermoelectric generator module taken along line 6 of FIG. 1;

FIG. 7 is an end sectional view of the thermoelectric generator module taken along line 7 of FIG. 1;

FIG. 8 is a perspective view of an embodiment of an insert that may be installed at an end of the thermoelectric generator module;

FIG. 9 is a perspective view of a further embodiment of an insert that may be installed at an end of the thermoelectric generator module;

FIG. 10 is an exploded perspective view of an embodiment of a wearable thermoelectric generator assembly configured for receiving a plurality of thermoelectric generator modules;

FIG. 11 is a cross-sectional diagrammatic view of an embodiment of a thermoelectric generator module illustrating a foil assembly comprising thermoelectric legs disposed on a substrate wherein a temperature gradient across the top and bottom heat coupling plates results in heat flow in a lengthwise direction through the thermoelectric legs;

FIG. 12 is a top view of the thermoelectric generator module taken along line 12 of FIG. 11 and illustrating a series of thermoelectric legs being arranged in rows on a substrate and further illustrating the alignment of thermally conductive strips with opposite ends of the thermoelectric legs in the rows causing heat to flow lengthwise through the thermoelectric legs;

FIG. 13 is a perspective view of a further embodiment of a thermoelectric generator module that may be integrated into a wearable thermoelectric generator assembly;

FIG. 14 is a top view of the thermoelectric generator module of FIG. 13;

FIG. 15 is an exploded view of the thermoelectric generator module of FIG. 13;

FIG. 16 is an end view of the thermoelectric generator module of FIG. 13;

FIG. 17 is a side view of the thermoelectric generator module of FIG. 13;

FIG. 18 is an end view of the thermoelectric generator module of FIG. 13 with an insert removed from the end of the module to illustrate a thermoelectric foil;

FIG. 19 is a top view of the thermoelectric generator module of FIG. 13 illustrating a plurality of thermoelectric legs deposited on a substrate of the thermoelectric foil;

FIG. 20 is a perspective view of an example of a side closeout that may be mounted on opposing sides of a thermoelectric generator module;

FIG. 21 is a perspective view of an example of an insert that may be mounted on one of opposing ends of a thermoelectric generator module;

FIG. 22 is an enlarged perspective view of a corner of a thermoelectric generator module illustrating an electrical contact clip extending into an interior for electrically connecting to a metal contact;

FIG. 23 is an enlarged perspective view of the thermoelectric generator module illustrating the assembly of one of the side closeouts with the top and bottom heat coupling plate;

FIG. 24 is an enlarged perspective view of the bottom heat coupling plate in contacting relation with a shelf protruding inwardly from the side closeout;

FIG. 25-28 are exploded views of a sequence of assembling the thermoelectric generator module of FIGS. 13-24;

FIG. 29 is a perspective view of a further embodiment of a thermoelectric generator module having a perimeter band formed of cured assembly adhesive;

FIG. 30 is an exploded perspective view of the embodiment of the thermoelectric generator module shown in FIG. 29;

FIG. 31 is a schematic sectional view of the embodiment of the thermoelectric generator module of FIG. 29 having a pair of mechanical clips extending through the assembly adhesive on opposing sides of the module;

FIG. 32 is a schematic sectional view of the embodiment of the thermoelectric generator module of FIG. 29 having a pair of electrical contact clips extended through the assembly adhesive on opposing sides of the module;

FIG. 33 is a perspective view of a further embodiment of a thermoelectric generator module having a perimeter band formed as an outer ring;

FIG. 34 is a perspective exploded view of the embodiment of the thermoelectric generator module shown in FIG. 33;

FIGS. 35-36 are exploded views illustrating a sequence for assembling the thermoelectric generator module embodiment shown in FIG. 33;

FIG. 37 is a top view of a further embodiment of a thermoelectric generator module having a portion of the thermoelectric legs electrically isolated from a remaining portion of the thermoelectric legs;

FIG. 38 is a perspective view of an embodiment of a multi-foil thermoelectric generator module having multiple thermoelectric foils in side-by-side arrangement;

FIG. 39 is a top view of the embodiment of the multi-foil thermoelectric generator of FIG. 38;

FIG. 40 is an exploded perspective view of an embodiment of a multi-foil thermoelectric generator module of FIG. 38;

FIG. 41 is a perspective view of an end of the multi-foil thermoelectric generator module of FIG. 38 with an insert removed illustrate structural support strips;

FIG. 42 is an enlarged view of an end of the multi-foil thermoelectric generator module showing an increased width of a structural support strip relative to the width of the thermally conductive strips;

FIG. 43 is a sectional side view of the thermoelectric generator module of FIG. 38 and illustrating a finger protruding from an inner surface of the insert;

FIG. 44 is a perspective view of a band configuration of a wearable thermoelectric generator assembly having a plurality of thermoelectric generator modules;

FIG. 45 is a top view of a further embodiment of a thermoelectric generator module wherein the perimeter band is configured as a frame assembly having an inner frame surrounded by the outer frame;

FIG. 46 is a side view of the thermoelectric generator module of FIG. 45;

FIG. 47 is a sectional side view of the thermoelectric generator module of FIG. 45;

FIG. 48 is an enlarged sectional view of a side of the thermoelectric generator module of FIG. 45;

FIG. 49 illustrates a flowchart including one or more operations that may be included in a method of manufacturing a thermoelectric generator module.

### DETAILED DESCRIPTION

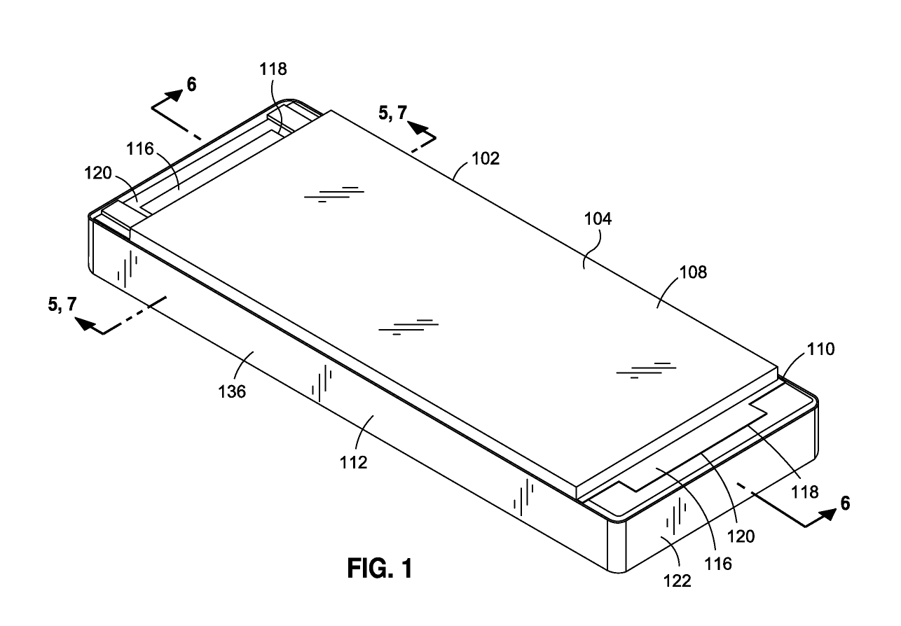

Referring now to the drawings wherein the showings are for purposes of illustrating various embodiments of the disclosure, shown in FIG. 1 is an embodiment of a thermoelectric generator module 102 as may be mounted in a wearable thermoelectric generator assembly 100. The thermoelectric generator module 102 may include a top heat coupling plate 104 and a bottom heat coupling plate 106. The thermoelectric generator module 102 may further include one or more thermoelectric foils 10 interposed between the top and bottom heat coupling plate 104, 106. Each thermoelectric foil 10 may include a series of thermoelectric legs 26. In addition, the thermoelectric generator module 102 may include a pair of inserts 120 mountable on one or more of the opposing ends of the thermoelectric generator module 102. The inserts 120 may be interconnectable to the top heat coupling plate 104 and/or to the bottom heat coupling plate 106. The thermoelectric generator module 102 may also include electrical contacts 130 such as a pair of electrical contact clips or a pair of integrated conductors (not shown) extending through an insert 120 and which may be electrically connected to opposing ends of the series of thermoelectric legs 26.

Advantageously, each one of the electrical contacts 130 such as the electrical contact clips may terminate at an upper tab 132 positioned on a top surface of the top heat coupling plate 104 to facilitate electrical connection of the thermoelectric generator module 102 to a load and/or to a flexible printed circuit 146 of a wearable thermoelectric generator assembly 100. A seal 136 may extend around a perimeter of the thermoelectric generator module 102 for sealing the top and bottom heat coupling plates 104, 106 with the inserts 120 and the electrical contacts 130 (e.g., electrical contact clips). The seal 136 may provide a barrier for protection of the thermoelectric foil 10 against the environment. As will be described in greater detail below, the top heat coupling plate 104 and the bottom heat coupling plate 106 may be provided with a head 108 that may protrude above a recessed portion 110. In an embodiment not shown, the top heat coupling plate 104 and/or the bottom heat coupling plate 106 may be configured with a head 108 that is larger in size (e.g., larger length and/or width) than the size of the top and/or bottom heat coupling plate 104, 106 such that the top and/or bottom heat coupling plate 104, 106 have a mushroom-shaped configuration. The head 108 may be integrally formed with each heat coupling plate 104, 106 or the head 108 may be separately mounted (e.g., adhesively-bonded with epoxy) to the heat coupling plate 104, 106.

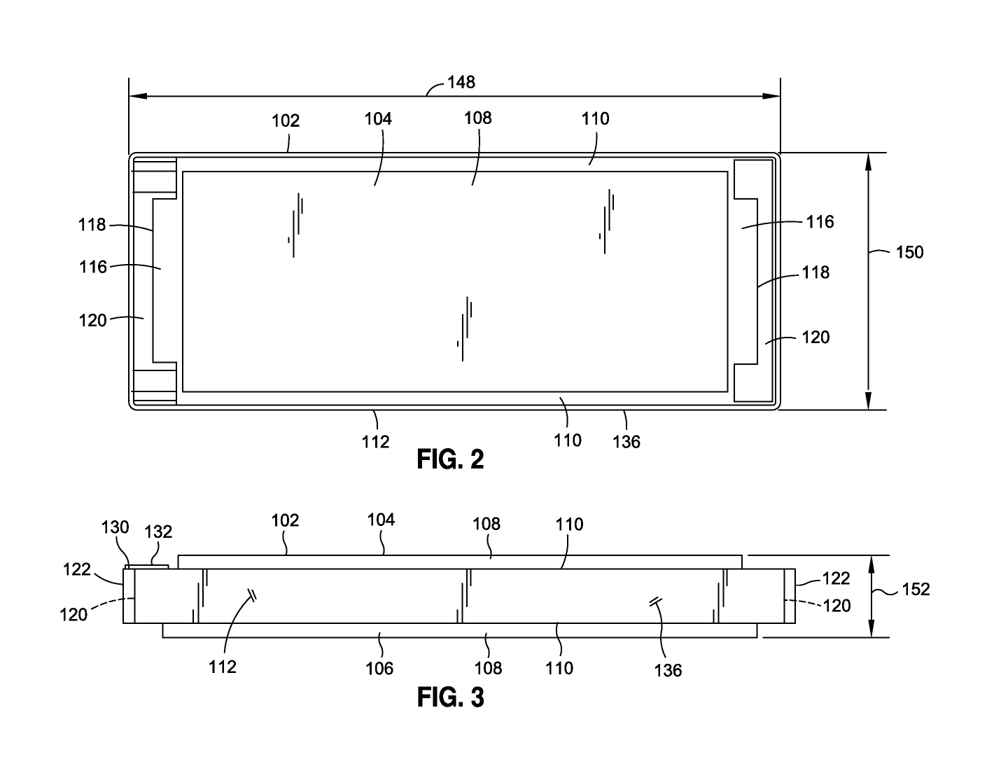

FIG. 2 is a top view of the embodiment of the thermoelectric generator module 102 of FIG. 1 which is shown having a rectangular configuration. The thermoelectric generator module 102 may be provided in a relatively compact size. For example, the thermoelectric generator module 102 may have outside dimensions comprising a length 148 of from approximately 10 mm to 50 mm, and a width 150 of from approximately 3 mm to 30 mm. However, the thermoelectric generator module 102 may have outside dimensions that are smaller or larger than the above-noted ranges. In addition, the thermoelectric generator module 102 may be provided in configurations other than a rectangular configuration shown in the Figures. For example, the thermoelectric generator module 102 may be provided in a square configuration or in any other configuration, without limitation. In this regard, the thermoelectric generator module 102 may be sized and configured complementary to the size and configuration of an opening 140 that may be formed in a matrix 138 of a wearable thermoelectric generator assembly 100 into which the thermoelectric generator module 102 may be mounted as described in greater detail below.

FIG. 3 is a side view of the embodiment of a thermoelectric generator module 102 FIG. 1. As can be seen, the head 108 of the top heat coupling plate 104 and/or the head 108 of the bottom heat coupling plate 106 may protrude beyond the recessed portion 110 of each heat coupling plate 104, 106. The thermoelectric generator module 102 may have a height 152 of from approximately 1 mm to 5 mm. The height 152 may be measured from an uppermost portion of the head 108 of the top heat coupling plate 104 to a lowermost portion of the head 108 of the bottom heat coupling plate 106. However, the thermoelectric generator module 102 may be provided in a height 152 that is larger or smaller than the above-noted height range. The thickness of each one of the heads 108 may also be complementary to a thickness of the matrix 138 of the wearable thermoelectric generator assembly 100 to provide optimal exposure of the heads 108 to the environment. For example, the thickness of the head 108 of the bottom heat coupling plate 106 may be optimized in consideration of the wearer's skin or apparel that the head 108 may contact.

The thickness of the head 108 of the top heat coupling plate 104 may be optimized in consideration of the air temperature to which the head 108 may be exposed. In this regard, the overall dimensions of a thermoelectric generator module 102 and the specific dimensions of the components (e.g., the top and bottom heat coupling plates 104, 106) may vary depending on the size of the matrix 138 and the application. Furthermore, a wearable thermoelectric generator assembly 100 may include any quantity of thermoelectric generator modules 102. For example, a wearable thermoelectric generator module 102 may include a single thermoelectric generator module 102 or multiple thermoelectric generator modules 102 which may be arranged in a single row, in several rows, or in other geometric arrangements.

Advantageously, when the thermoelectric generator module 102 is integrated or mounted in a matrix 138, the head 108 on the top heat coupling plate 104 and/or bottom heat coupling plate 106 may minimize or absorb tensile forces that may be imposed on the thermoelectric generator module 102 as result of contact or impact of a thermoelectric generator module against a hard surface and which may otherwise urge the top and bottom heat coupling plate away from one another causing a disruption in the thermal and electrical connections within the thermoelectric generator module 102. In this regard, the thermoelectric generator module 102 embodiment disclosed herein may provide improved protection against tensile and shear forces relative to a thermoelectric generator system as disclosed in U.S. Patent Publication No. 2013/0087180 to Stark, and entitled WEARABLE THERMOELECTRIC GENERATOR SYSTEM, the entire contents of which is incorporated by reference herein.

In the thermoelectric generator module 102 disclosed herein, the protrusion of the head 108 of the top heat coupling plate 104 and/or the head 108 of the bottom heat coupling plate 106 beyond the recessed portion 110 of each heat coupling plate 104, 106 results in an improvement in the integration of one or more thermoelectric generator modules 102 within a matrix 138 of a wearable thermoelectric generator assembly 100 such as a wristband, an armband, a patch, or other wearable configurations. More specifically, in an embodiment, the matrix material of a wearable thermoelectric generator assembly 100 may be positioned over the recessed portion 110 surrounding the head 108 of the top heat coupling plate 104 and/or bottom heat coupling plate 106 in a manner such that only the heads 108 of the heat coupling plates 104, 106 are exposed to the environment, thereby avoiding tensile forces and/or shear forces on the thermoelectric generator module 102.

The head 108 of the top heat coupling plate 104 and the head 108 of the bottom heat coupling plate 106 may be provided in any size, shape, configuration, and surface structure and which may be optimized for a given application. For example, one or more of the thermoelectric generator modules 102 as disclosed herein may be mounted in a wearable thermoelectric generator assembly 100 for providing power to a load such as a microelectronic device. For such an implementation, the head 108 of the bottom heat coupling plate 106 and the top heat coupling plate 104 may have a different size, shape and surface texture. In this regard, the heads 108 of the top and bottom heat coupling plates 104, 106 may be provided in any shape for improved aesthetic design and/or increased heat flow. In an embodiment, the head 108 of the heat coupling plates 104, 106 may have one or more attached (e.g., adhesively bonded or fastened) components (not shown) of different size (e.g., larger or smaller) than the head 108 and which may have relatively low thermal resistance and relatively high emissivity to increase heat flow through the thermoelectric generator module 102 and/or to improve the aesthetic design. In an embodiment, the head 108 of the top heat coupling plate 104 and/or the head 108 of the bottom heat coupling plate 106 may be provided in an oval, round, dome, or flat configuration as shown in FIG. 1. In an embodiment, the bottom heat coupling plate 106 may have a smooth surface for contact with the skin or apparel of a wearer of the thermoelectric generator assembly 100. In contrast, the surface of the top heat coupling plate 104 may be structured with fins, dimples, pins, or other surface features to increase the surface area of the top heat coupling plate 104 for improved heat exchange with the environment.

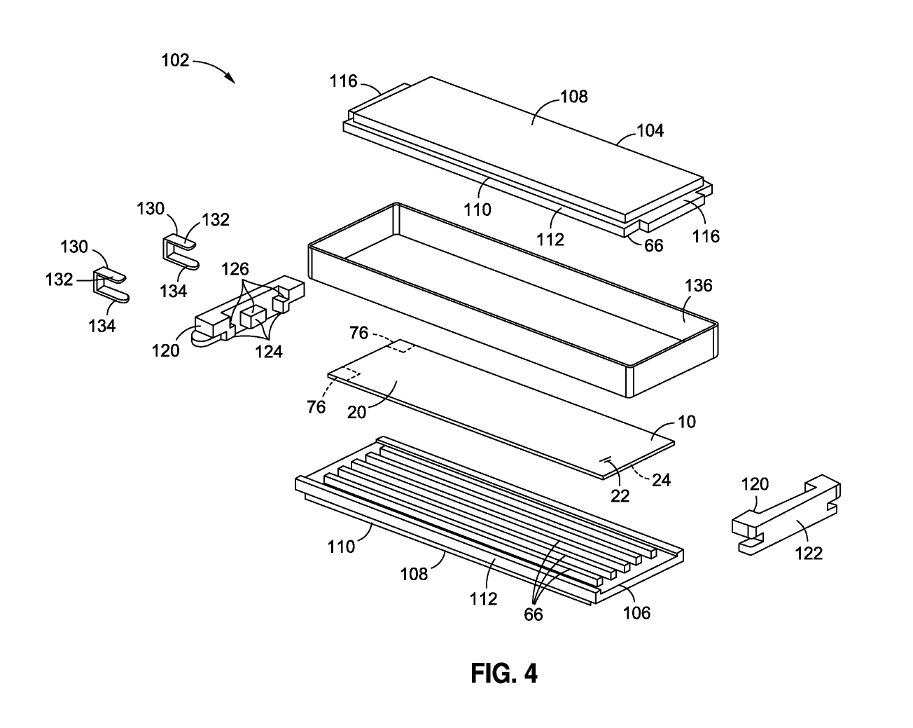

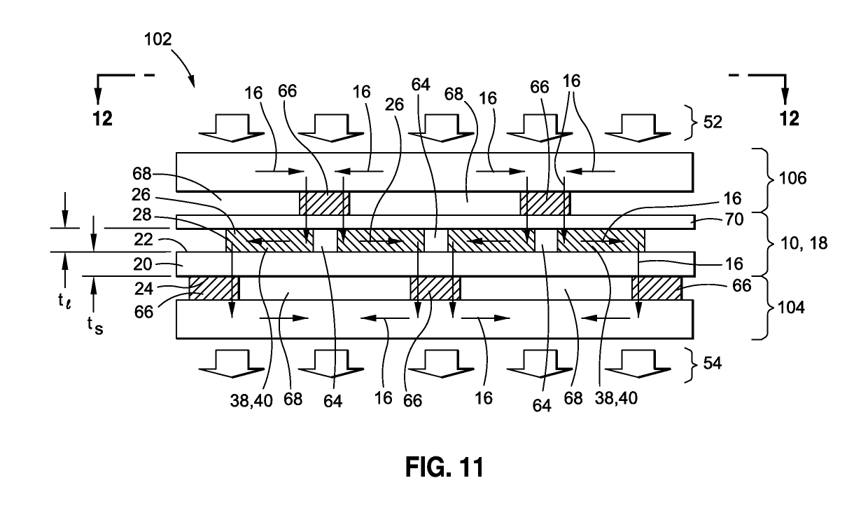

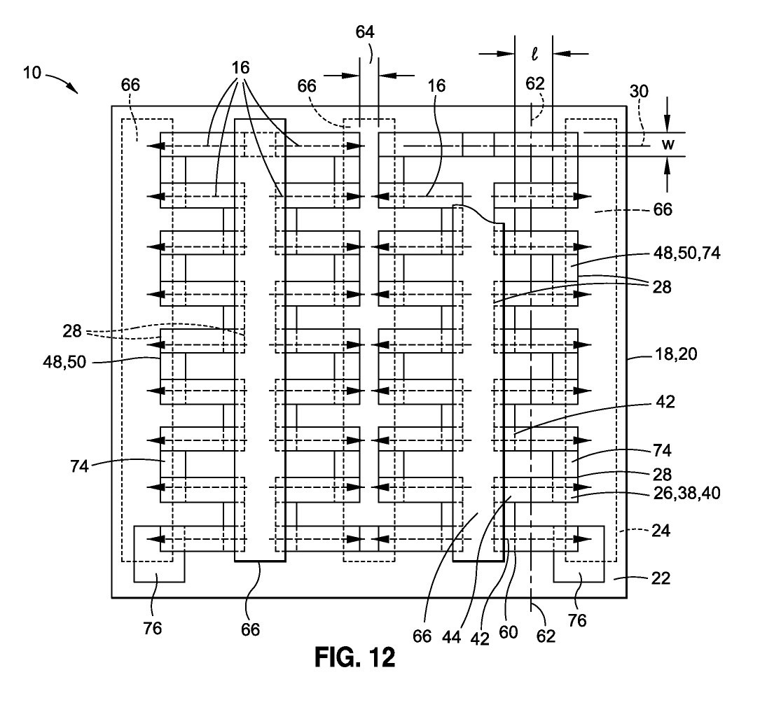

FIG. 4 is an exploded view of an embodiment of the thermoelectric generator module 102. The top heat coupling plate 104 and/or the bottom heat coupling plate 106 may have thermally conductive strips 66. The thermally conductive strips 66 may be integrally formed along inner surfaces of the top heat coupling plate 104 and the bottom heat coupling plate 106. The thermoelectric foil 10 may be provided in a planar arrangement as disclosed in U.S. Patent Publication No. 2011/0094556 to Stark, and PLANAR THERMOELECTRIC GENERATOR, the entire contents of which is incorporated by reference herein. The thermoelectric foil 10 may include a substrate 20 that may be interposed between the thermally conductive strips 66 of the top and bottom heat coupling plates 104, 106. As described in greater detail below, the substrate 20 has upper and lower substrate surfaces 22, 24 (FIG. 11) and may be formed of an electrically insulating material having a relatively low thermal conductivity. As shown in FIG. 12, a series of thermoelectric legs 26 may be formed on the substrate 20. The series of thermoelectric legs 26 may be formed of alternating dissimilar materials arranged in at least one row 60 on at least one of the upper and lower substrate surfaces 22, 24 and terminating at metal contacts 76 at opposing ends of the series of thermoelectric legs 26. The metal contacts 76 may facilitate electrical connection of the thermoelectric legs 26 to a load and/or to a flexible printed circuit 146. In an embodiment, the metal contacts 76 of the thermoelectric foil 10 may be located on an underside of the substrate 20 at the bottom heat coupling plate 106. A flexible printed circuit 146 may be mounted on the bottom heat coupling plate 106 and may be electrically connected to the electrical contacts 130 (e.g., contact clips) on the same thermal side as the contact clips which would advantageously minimize thermal shunting.

In FIG. 4, the electrical contacts 130 may be configured as electrical contact clips and may have lower tabs 134 that may be electrically connectable to the metal contacts 76 on the opposing ends of the series of thermoelectric legs 26. For example, the lower tabs 134 may be formed at an angle to allow slidable installation of the inserts 120 onto the thermoelectric generator module 102 such that the lower tabs 134 overlap the metal contacts 76 (i.e., the electrical contacts) of the thermoelectric foil 10 in the final position. The lower tabs 134 may be provided with electrically conductive adhesive for adhesively bonding with the metal contacts 76 when the inserts 120 and the electrical contacts 130 are assembled with the thermoelectric foil 10 and the top and bottom heat coupling plates 104, 106. The electrical contacts 130 and/or the lower tabs 134 thereof may be formed of highly electrically conductive and solderable material, such as tin-coated copper or other highly conductive or solderable material. In an embodiment, the electrical contacts 130 (e.g., electrical contact clips) may be formed of a spring-like material such as spring steel or other high-yield-strength material to allow the electrical contact clips to clamp onto the insert 120 and hold on to the insert 120.

In an embodiment, the top and bottom heat coupling plate 104, 106 may be adhesively bonded to the inserts 120 and the electrical contacts 130 using assembly adhesive 118, although the components may be coupled by mechanical fastening, or by a combination of adhesive bonding, mechanical fastening, or over-molding. In an embodiment, the electrical contacts 130 may be pre-assembled with the insert 120 on one end of the thermoelectric generator module 102. In this regard, the electrical contacts 130 may be adhesively bonded to the insert 120 to simplify the assembly process for the thermoelectric generator module 102. Alternatively, the inserts 120 may be installed without electrical contacts 130 to facilitate the assembly of the thermoelectric generator module 102, with the exception of the electrical connection of the thermoelectric generator module 102 with a load which may be performed at a later time.

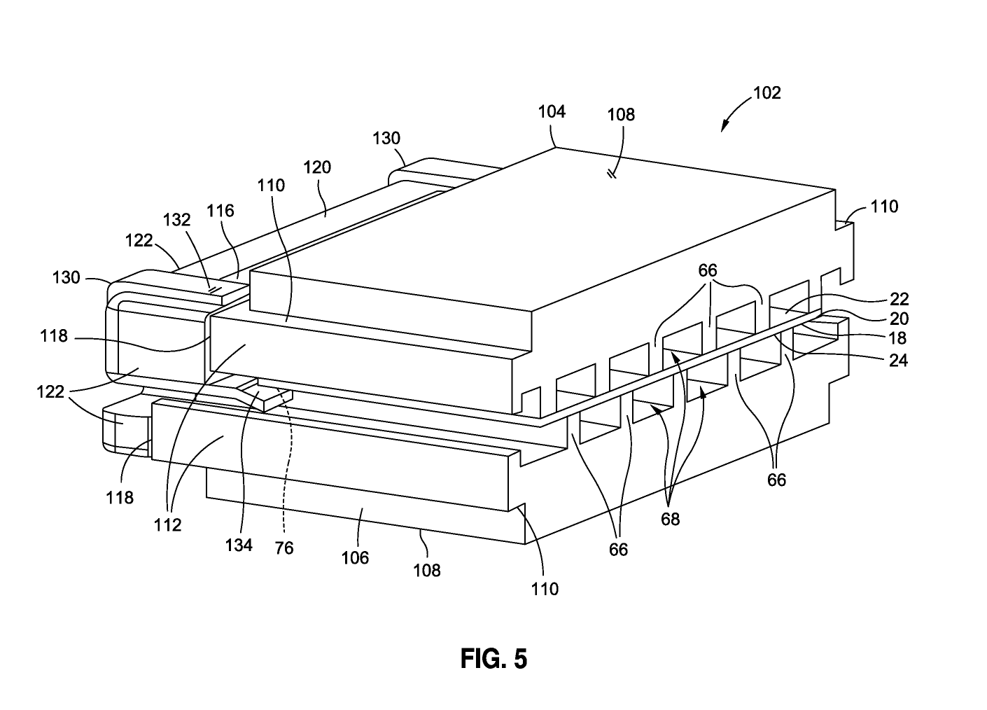

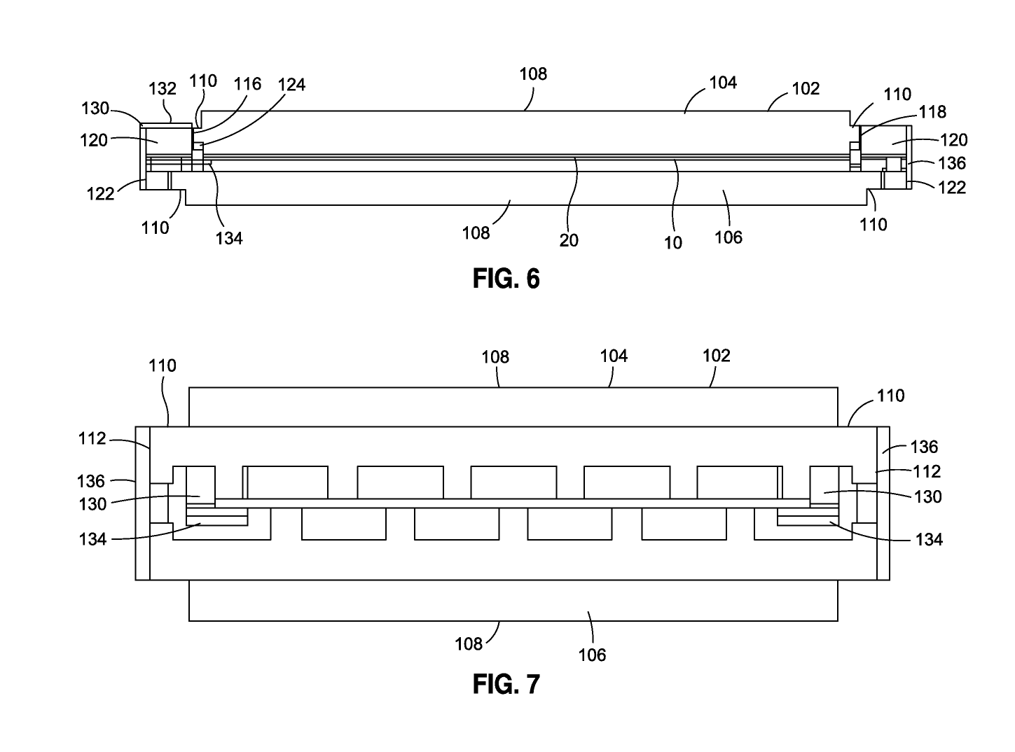

In FIG. 4-7, each one of the electrical contacts 130 may have a C-shaped configuration and may extend outwardly from the lower tab 134. In this regard, the electrical contacts 130 may extend upwardly along the external side 122 of the inserts 120 and may be folded over horizontally over the top heat coupling plate 104 and may terminate at an upper tab 132. The upper tab 132 may be disposed against a recessed portion 110 on top of the top heat coupling plate 104 to facilitate the electrical connection with a flexible printed circuit board 146. In an embodiment, the electrical contacts 130 may be formed with an extension (not shown) extending along a top side of the insert 120 or recessed portion 110 to increase the length of the metal path from the upper tab 132 of the electrical contacts 130 to the lower tab 130 of the electrical contacts 130 and thereby increasing the thermal resistance. In this manner, soldering of the upper tab 132 to the flexible printed circuit board 146 may result in a reduced amount of heat impact at the electrical connection between the lower tab 134 and the thermoelectric foil 10.

Advantageously, the electrical contacts 130 increase the height of the electrical connection for the thermoelectric foil 10 to a level slightly above the height of the top heat coupling plate 104 along the recessed portion. The electrical contacts 130 significantly improve the electrical connection of the thermoelectric foil 10 with a load such as a flexible printed circuit 146. A further advantage provided by locating the electrical contacts 130 (e.g., the upper tabs 132) slightly above the top heat coupling plate 104 is that the flexible printed circuit 146 may be in substantially the same plane as the top heat coupling plate 104 which may improve thermal performance relative to an arrangement wherein the flexible printed circuit 146 is positioned between the top and bottom heat coupling plate 104, 106. In this regard, the flexible printed circuit 146 may include copper traces (not shown) and components that may act as a thermal sink or thermal source with a resulting improvement in thermal performance. In an embodiment, the electrical contacts 130 may be electrically connected to a flexible printed circuit 146 having components (not shown) located on either side of the flexible printed circuit 146. The upper tabs 132 of electrical contacts 130 may be electrically connected to the flexible printed circuit 146 using assembly techniques such as hot bar soldering, adhesive dispensing, or other electrical connection techniques.

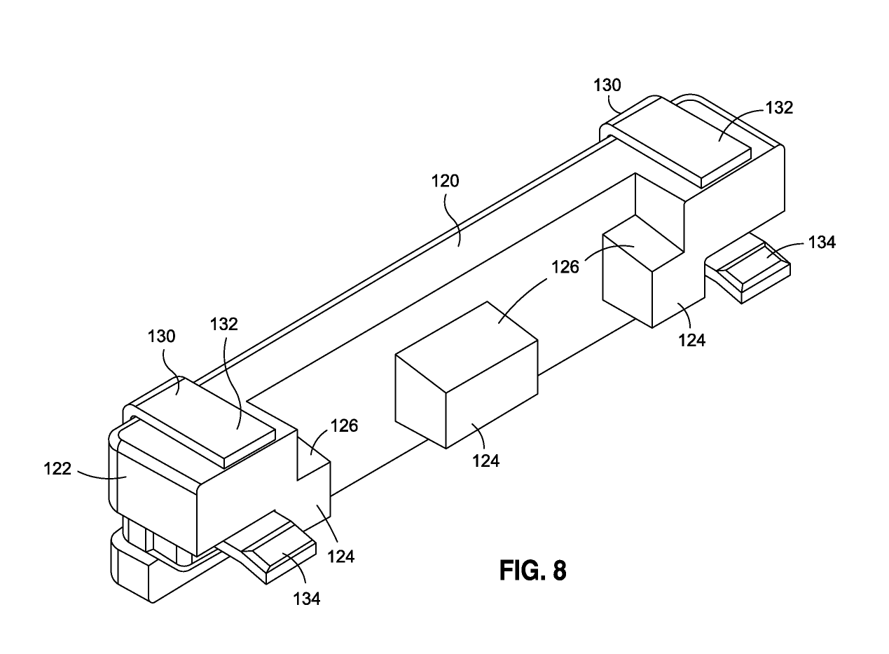

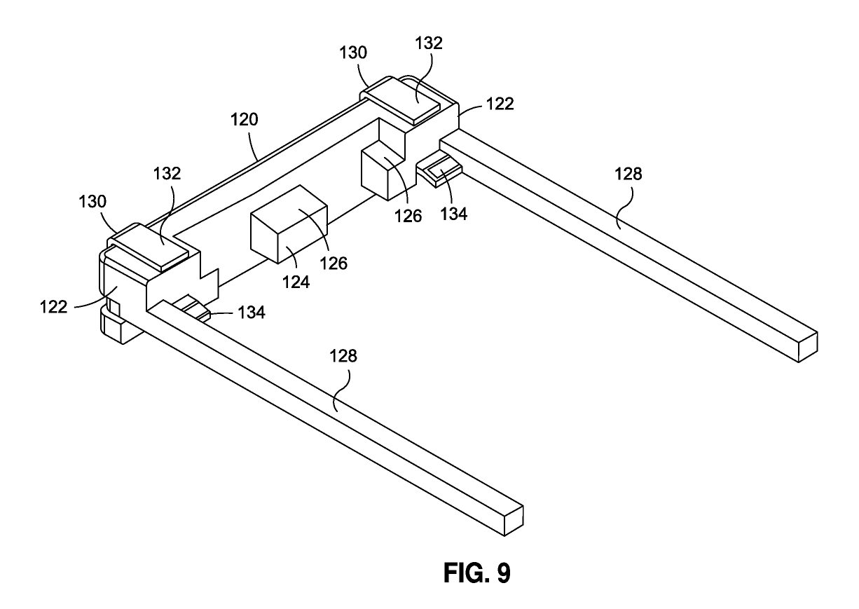

In FIG. 4-6, the inserts 120 may be mountable on opposite ends of the thermoelectric foil 10 and may be connectable to the ends of the top heat coupling plate 104 and bottom heat coupling plate 106. In an embodiment, the top heat coupling plate 104 may have protruding end tabs 116 formed on opposing ends of the top of heat coupling plate. The end tabs 116 may be supported on one or more shelves 124 that may be formed on an inner surface of each insert 120. As shown in FIG. 8, in an embodiment, the shelves 124 may be provided with sloped surfaces 126 for guiding the slidable installation of the inserts 120 onto the ends of the top heat coupling plate 104. In an alternative embodiment shown in FIG. 9, the inserts 120 may be provided with extended sides 128 to increase the mechanical stability (e.g., resistance to bending or flexing) of the thermoelectric generator module 102. By integrally forming the extended sides 128 with the inserts 120, the total part count for the thermoelectric generator module 102 is reduced relative to a thermoelectric generator module 102 embodiment having separate spacers (not shown) for increasing the mechanical stability of the thermoelectric generator module 102.

In FIG. 4-7, the inserts 120 advantageously protect the thermoelectric foil 10 from damage as may otherwise occur as a result of mechanical impact of the thermoelectric generator module 102 with a hard surface or object. In addition, the inserts 120 may facilitate the sealing of the opposing ends of the thermoelectric generator module 102, and provide an external side 122 surface to facilitate the application of the external seal 136 around the thermoelectric generator module 102 as described below. In an embodiment, the inserts 120 may be comprised of material having relatively low thermal conductivity to promote heat flow through the thermoelectric foil 10. In an embodiment, the inserts 120 may be comprised of material having a thermal conductivity of less than approximately 0.2 W/mK, although the inserts 120 may be formed of material having a higher thermal conductivity than 0.2 W/mK.

In an embodiment not shown, the thermoelectric generator module 102 may be configured for electrically connecting to electrical components mounted on both sides of a flexible printed circuit 146 of the wearable thermoelectric generator assembly 100. Such an arrangement may require that the flexible printed circuit 146 is connected to the thermoelectric generator module 102 at an approximate mid-plane of the thermoelectric generator module 102. In a further embodiment not shown, the electrical contacts 130 may be replaced by pins (not shown) that may be extended vertically through the inserts 120 and which may be configured to electrical connect with the metal contacts 76 (e.g., electrical contacts) of the thermoelectric foil 10. For example, a lower end of the pins may be coupled to an angled lower tab 134 that may be electrically coupled to the metal contacts 76 of the thermoelectric foil 10. In an embodiment, an upper end of the pins may be electrically connected to a flexible printed circuit board 146 by means of a metal foil (not shown) that may be applied along the top of the thermoelectric generator module 102 such as along the recessed portion 110 of the top heat coupling plate 104 or along the top of the insert 120. Such pins may be preassembled or over-molded with the insert 120 and may avoid the need to adhesively bond clips or pins to the insert 120.

In another embodiment not shown, the thermoelectric foil 10 may be provided with additional pairs of electrical contacts (e.g., metal contacts 76) for connecting the thermoelectric foil 10 to additional devices. For example, the thermoelectric foil 10 may be provided with up to four (4) metal contacts 76 such that a pair of the metal contacts 76 may be connected to an integrated sensor such as a temperature sensor. Even further, the thermoelectric generator module 102 may be provided in an embodiment having a separate series of thermocouples 48 dedicated to providing a voltage proportional to the temperature difference across the thermoelectric generator module 102 such as, for example, providing maximum power point tracking capability. Furthermore the four (4) metal contacts 76 of the thermoelectric foil 10 may provide the capability for splitting the thermoelectric foil 10 into two (2) electrically separated portions for external wiring in series or in parallel, depending on the power requirements of the load (e.g., the final electronics) and the temperature difference available across the thermoelectric generator module 102.

In FIGS. 4, and 6-7, the thermoelectric generator module 102 may be provided with a seal 136 extending around a perimeter of the thermoelectric generator module 102 for sealing the thermoelectric generator module 102. The seal 136 may extend around the external sides 122 of the inserts 120 and the external sides 112 of the top and bottom heat coupling plates 104, 106. The inserts 120 may be provided with external round (e.g., radiused) corners to improve the sealing capability of the seal 136. In this regard, the rounded corners may facilitate the conforming of the seal 136 to the sides of the thermoelectric generator module 102. In an embodiment, the seal 136 may comprise a sealant such as, for example, one-side adhesive tape, shrink-fit tubing, a dispensed sealing material, or other sealing means such as for air-tight sealing of the thermoelectric generator module 102. The surface area of the external sides 112 of the top and bottom heat coupling plates 104, 106, (e.g., the portions not covered by the inserts 120) may be enlarged as a means to increase the contact area for a sealant to improve adhesion of the sealant to the top and bottom heat coupling plates 104, 106 and to improve mechanical stability and level of air-tightness. In an embodiment, the interior of the thermoelectric generator module 102 may be filled with a gas that may have a lower thermal conductivity than air such as, for example, argon, krypton, or neon.

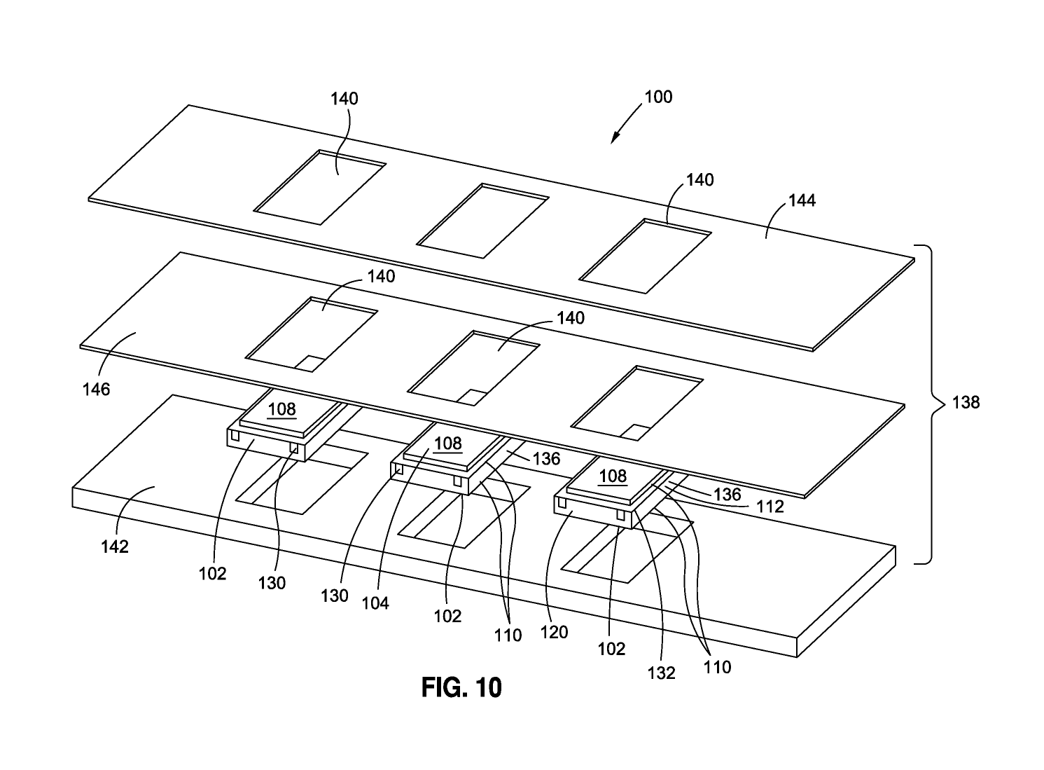

In FIG. 10, shown is a matrix 138 of a wearable thermoelectric generator assembly 100 into which one or more of the thermoelectric generator modules 102 may be mounted. The matrix 138 may include a series of openings 140. Each opening 140 may be configured to receive a thermoelectric generator module 102. The matrix 138 may be configured such that the heads 108 of the top and bottom heat coupling plates 104, 106 are exposed to an environment, and a remaining portion of the thermoelectric generator module 102 is non-exposed to the environment. For example, the head 108 of the bottom heat coupling plate 106 may be configured to be exposed to a wearer skin or apparel. The head 108 of the top heat coupling plate 104 may be configured to be exposed to ambient air. The matrix 138 may comprise the above-mentioned flexible printed circuit 146 which may be sandwiched between a bottom layer 142 of the matrix 138 and a top layer 144 of the matrix 138. The opening 140 in the flexible printed circuit 146 may be configured complementary to a shape of the head 108 of the top heat coupling plate 104 such that the flexible printed circuit 146 is in contact with the recessed portion 110 and is electrically connected to the upper tabs 132 of the electrical contacts 130, pins, or other electrical connection means.

In FIG. 10, the flexible printed circuit 146 may include one or more electronic components such as power conditioning for the thermoelectric foil 10, and final electronics or load to be powered by the one or more thermoelectric generator modules 102. The matrix 138 may include one or more thermally insulating layers that may be integrated into the matrix 138 between the top and bottom heat coupling plates 104, 106. The matrix 138 may be fabricated using various assembly technologies including, but not limited to, heat pressing, over-molding, lamination, or packaging of glued, prefinished layers. The matrix 138 may be formed of any one of a variety of different materials. For example, the matrix 138 may be formed of plastic, rubber, textile, synthetic, metallic, leather, or other materials or combinations thereof. The matrix 138 may be formed as a stack of layers including a top layer 144 and a bottom layer 142. The stack of layers for the matrix 138 may facilitate the integration of various functional layers. The stack of multiple layers may reduce parasitic parallel heat flow through the matrix 138 which may increase the overall thermal resistance of the thermoelectric generator assembly 100 and the temperature difference across a thermoelectric generator module 102.

In an embodiment, the matrix 138 material may have a relatively low thermal conductivity which may be achieved by using materials with thermal conductivities less than approximately 0.2 W/mK. However, outer layers of the matrix 138 such as at the bottom and/or the top of the matrix 138 may be formed of material such as metallic material, or a combination of materials providing a relatively high thermal conductivity such as in the range of approximately 20 W/mK to 160 W/mK as a means to enlarge the surface of the bottom heat coupling plate 106 (e.g. the heat collector) and/or top heat coupling plate 104 (e.g., the heat exchanger) for increased heat flow through the thermoelectric generator module 102. In such an embodiment, the bottom layer 142 and/or the top layer 144 of the matrix 138 may be directly thermally coupled to the recessed portion 110 of the top and bottom heat coupling plates 104, 106 not covered by the inserts 120, and the flexile printed circuit 146.

In an embodiment, the matrix 138 may be implemented in a wearable thermoelectric generator assembly 100 which may be provided in any one of a variety of different wearable configurations including, but not limited to, a wristband, an arm band, and a patch. Such embodiments may be placed in direct or indirect contact with human skin which may generate moisture due to perspiration. In an embodiment, the matrix 138 may provide a structure capable of wicking moisture through micro channels formed in the matrix 138, or a textile or fabric that may wrap around the matrix 138 and connect to a top layer 144 of the matrix 138. In such an arrangement, moisture such as from perspiration may evaporate resulting in cooling down of the surface. If the matrix 138 includes a surface layer having a high thermal conductivity that is thermally attached to the top heat coupling plate 104, then the top heat coupling plate 104 may be cooled down which may advantageously result in a larger temperature difference across the thermoelectric generator module 102 and a higher power output for the thermoelectric generator module 102.

In FIG. 11-12, shown are diagrammatic views of an embodiment of a thermoelectric generator module 102 having a planar arrangement. As indicated above, the thermoelectric generator module 102 may comprise a thin film thermopile structure in an in-plane configuration as disclosed in the above-mentioned U.S. Patent Publication No. 2011/0094556 entitled PLANAR THERMOELECTRIC GENERATOR. In the diagrammatic section view of FIG. 11, the bottom heat coupling plate 106 is located above the top heat coupling plate 104. In an embodiment of a thermoelectric generator module 102, heat from a wearer's skin may flow into the head 108 of the bottom heat coupling plate 106 and may flow out of the head 108 of the top heat coupling plate 104 which may be exposed to ambient air. However, the thermoelectric generator module 102 advantageously allows for the generation of electricity regardless of whether heat flows from the top heat coupling plate 104 toward the bottom heat coupling plate 106, or from the bottom heat coupling plate 106 toward the top heat coupling plate 104.

As indicated above, the thermoelectric foil 10 includes thermoelectric legs 26 disposed on the substrate 20 formed of an electrically insulating material having a relatively low thermal conductivity. A series of thermoelectric legs 26 formed of alternating dissimilar materials are arranged in at least one row 60 on at least one of the upper and lower substrate 20 surfaces and terminating at metal contacts 76 at opposing ends of the series of thermoelectric legs 26. The metal contacts 76 may be electrically coupled to the electrical contact clips 130 or other connection means for electrical connection to a load.

In FIG. 12, each one of the thermoelectric legs 26 may define a leg axis 30 that may be oriented in non-parallel relation to the row axis 62. The thermally conductive strips 66 of the top and bottom heat coupling plates 104, 106 may be aligned with opposite ends 28 of the thermoelectric legs 26 in the row 60 such that one end 28 of the thermoelectric legs 26 is in thermal contact with the top heat coupling plate 104, and the opposite end 28 of the thermoelectric legs 26 is in thermal contact with the bottom heat coupling plate 106. The thermally conductive strips 66 may define thermal gaps 68 between the thermoelectric legs 26 and the top and bottom heat coupling plates 104, 106 causing heat to flow lengthwise through the thermoelectric legs 26.

In FIG. 12, the thermally conductive strips 66 are arranged to facilitate the flow of heat between the top and bottom heat coupling plates 104, 106. The thermally conductive strips 66 located adjacent to the top heat coupling plate 104 are arranged in alignment with the ends 28 of the thermoelectric legs 26 of an adjacent pair of rows 60 while the thermally conductive strips 66 that are located adjacent the bottom heat coupling plate 106 are aligned with the opposite leg ends 28 of the thermoelectric legs 26 in an adjacent pair of rows 60. Notably, the thermally conductive strips 66 are arranged in spaced relation to one another to form thermal gaps 68 which serve as areas of high thermal resistance causing a majority of the heat to flow through the thermoelectric legs 26. In this manner, the thermally conductive strips 66 are placed in thermal contact with the opposite leg ends 28 of each one of the thermoelectric legs 26 such that heat flows along the heat flow direction 16 indicated by the arrows in FIG. 11. In this regard, heat flows lengthwise through each one of the thermoelectric legs 26 in order to produce a voltage potential across the thermoelectric legs 26.

Referring to FIG. 12, shown is a top view of an embodiment of a thermoelectric generator module 102 illustrating the direction of heat flow through the thermoelectric legs 26. As can be seen, the thermoelectric legs 26 are arranged as a series of alternating thermoelectric legs 26 of dissimilar materials. For example, the thermoelectric legs 26 may alternate from different types of semiconductor materials such as n-type and p-type legs 42, 44. The substrate 20 is preferably formed of an electrically insulating material which preferably has a relatively low thermal conductivity. For example, in a preferred embodiment, the substrate 20 may be formed of polyimide material such as Kapton® commercially available from E. I. duPont de Nemours & Co., Inc. However, the substrate 20 may be formed of any suitable material having a relatively low thermal conductivity and which is preferably electrically insulating.

The substrate 20 may be provided in any suitable substrate thickness tₛ including, but not limited to, a substrate thickness tₛ in the range of from 5 microns to 100 microns. Preferably, the substrate 20 such as polyimide film is provided in a substrate thickness tₛ of 7.5 microns although 12.5 microns may also be a suitable substrate thickness L. The substrate 20 is preferably formed of a material that is mechanically stable at the elevated temperatures associated with deposition of semiconductor films and with the annealing procedure. Furthermore, the substrate 20 is preferably a relatively thin material having dimensional stability and which is resistant against chemicals such as acids commonly used in the process for structuring the thermoelectric legs 26 following deposition on the substrate 20. In FIG. 11, the thermoelectric legs 26 are preferably provided in a thickness which is compatible with the substrate material as well as with the application for which the thermoelectric generator module 102 is employed. For example, thermoelectric legs 26 may be formed of semiconductor material 38 in a leg thickness tₛ range of from 15 microns up to approximately 100 microns or more and, preferably, in a thickness tₛ of approximately 25 microns.

Disclosed herein is a method of manufacturing an embodiment of a wearable thermoelectric generator assembly 100 such as the embodiment shown in FIGS. 1 to 12. The method may include fabricating the above-mentioned components of the thermoelectric generator module 102 including the thermoelectric foil 10, the top heat coupling plate 104, the bottom heat coupling plate 106, a pair of inserts 120, and a pair of electrical contacts 130 (e.g., electrical contact clips). The method may include fabricating a flexible printed circuit board 146 having electronic circuitry, and fabricating a matrix 138 using any one or more of the above-mentioned materials and assembly techniques. The method may include forming openings 140 in the matrix 138 that are complementary to the size, shape, and configuration of the thermoelectric generator modules 102 to be installed therewithin.

The method may additionally include aligning and assembling the bottom heat coupling plate 106 to the thermoelectric foil 10 as shown in FIG. 4. The method may additionally include aligning and assembling the top heat coupling plate 104 to the thermoelectric foil 10 on a side thereof opposite the bottom heat coupling plate 106. The method may include installing the inserts 120 on opposing ends of the thermoelectric generator module 102. The electrical contacts 130 may optionally be pre-assembled to the inserts 120 such as over-molding. The inserts 120 may be assembled to the top and bottom heat coupling plates 104, 106 such as by using an assembly adhesive 118. The method may further include electrically connecting the electrical contacts 130 to the metal contacts 76 of the thermoelectric foil 10 such as by using electrically conductive adhesive that may be applied to the angled lower tabs 134 of the electrical contacts 130.

The method may additionally include filling an interior of the thermoelectric generator module 102 with gas that may have a thermal conductivity that is less than the thermal conductivity of air. The method may further include installing a seal 136 around external sides 112 of the thermoelectric generator module 102 such as by applying an adhesive tape or other sealing means around the external sides 112 of the top and bottom heat coupling plates 104, 106 and the external sides 122 of the inserts 120. The method may include functional testing of the performance of the thermoelectric generator module 102 prior to installing the thermoelectric generator module 102 in the wearable thermoelectric generator assembly 100.

Following functional testing of the thermoelectric generator module 102, the method may include electrically connecting the thermoelectric generator module 102 to a flexible printed circuit 146 such as by soldering the upper tabs 132 of the electrical contacts 130 to the flexible printed circuit 146. The method may further include integrating the flexible printed circuit 146 into a matrix 138 of a wearable thermoelectric assembly as described above. Following assembly of the thermoelectric generator assembly 100, the method may include testing the performance of the thermoelectric generator assembly 100.

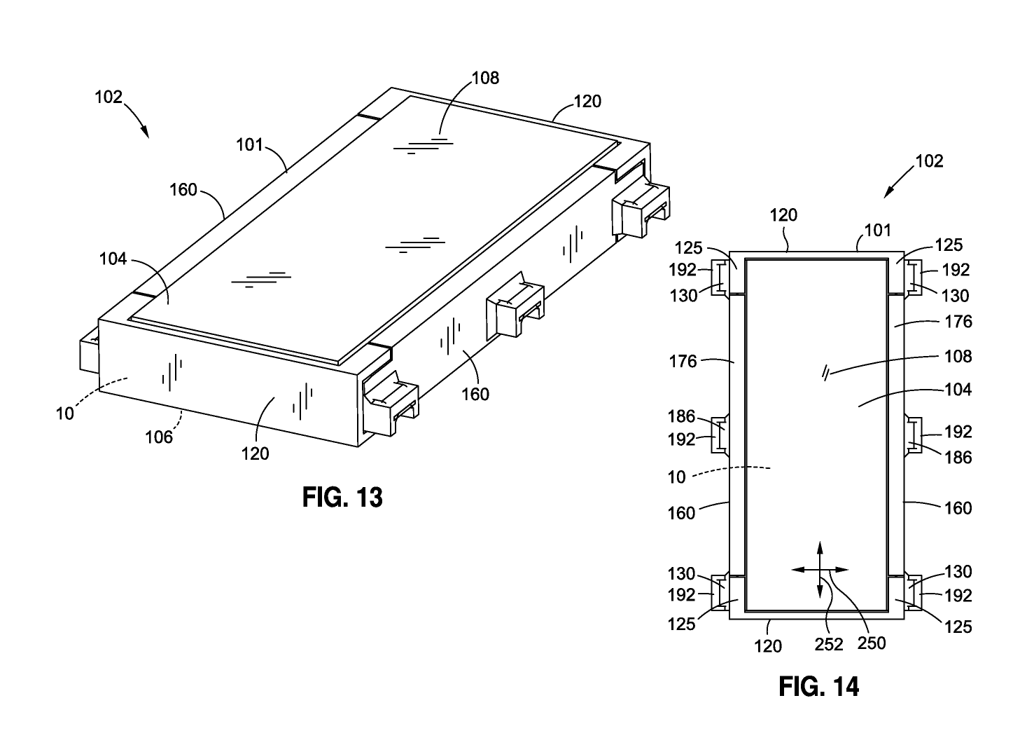

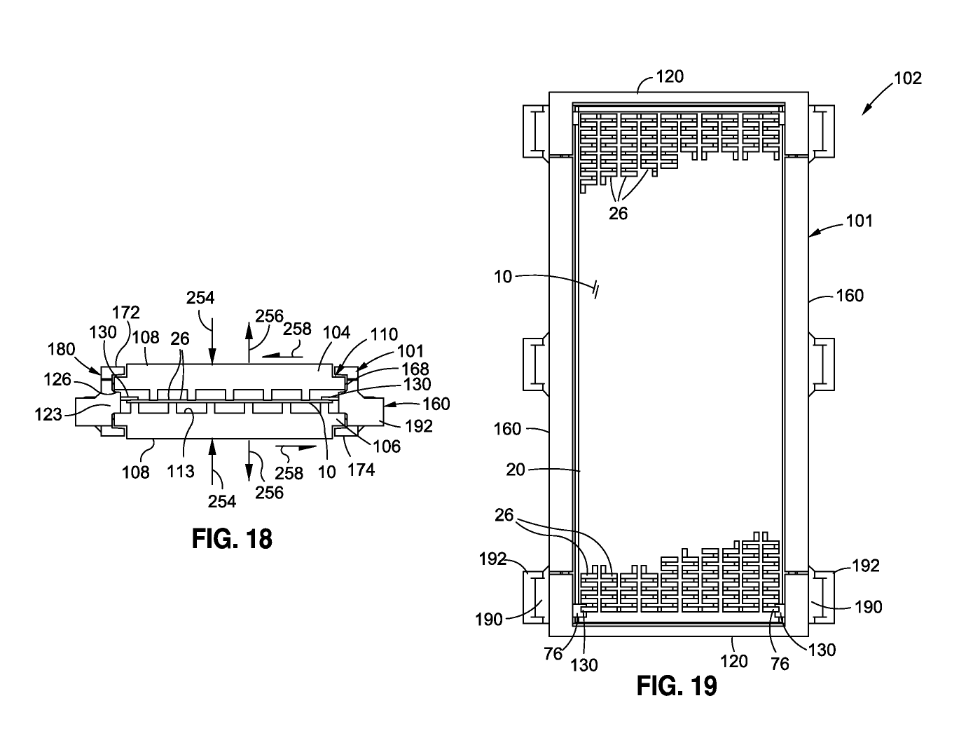

FIG. 13 shows a further embodiment of a thermoelectric generator module 102 and which may be integrated into a wearable thermoelectric generator assembly 100. The thermoelectric generator module 102 may be configured generally similar to the thermoelectric generator module 102 shown in FIGS. 1-12 in the sense that the thermoelectric generator module 102 shown in FIG. 13 may include a thermoelectric foil 10 sandwiched between a top and bottom heat coupling plate 104, 106. As indicated above, the thermoelectric foil 10 may be provided in a planar arrangement as disclosed in U.S. Patent Publication No. 2011/0094556 to Stark. In addition, the thermoelectric generator module 102 may include a perimeter band 101 extending around a perimeter of the assembled top and bottom heat coupling plates 104, 106 to provide mechanical stability for the thermoelectric generator module 102 against compressive forces 254 (FIG. 18), tensile forces 256 (FIG. 18), and shear forces 258 (FIG. 18) that may be imposed on the module 102 during use.

The perimeter band 101 surrounds the perimeter edges of the top and bottom heat coupling plate 104, 106 and encapsulates the thermoelectric foil 10. The perimeter band 101 may be formed of material having a relatively high thermal resistance such that a majority of heat flow between the top and bottom heat coupling plate 104, 106 passes through the thermoelectric legs 26 (FIG. 19) of the thermoelectric foil 10 sandwiched between the top and bottom heat coupling plate 104, 106. In addition, the perimeter band 101 material may be a relatively high-strength material with high stiffness to rigidly encapsulate the thermoelectric foil 10 and minimize flexing of the thermoelectric foil 10. In some examples, the perimeter band 101 may be formed as an assembly of two (2) or more components such as the side closeouts 160 and inserts 120 shown in FIGS. 13-24, and described below. In other examples, the perimeter band 101 may be formed as an outer ring 202 of unitary construction as shown in FIGS. 33-36, and described below. In the present disclosure, the outer ring 202 may be provided in a shape that is complementary to the geometric profile of the top and bottom heat coupling plate 104, 106 that the outer ring 202 circumscribes. For example, the outer ring 202 is not limited to a rounded shape, and may be provided in a rectangular shape, a square shape, or any other shape that matches the shape of the top and bottom heat coupling plate 104, 106.

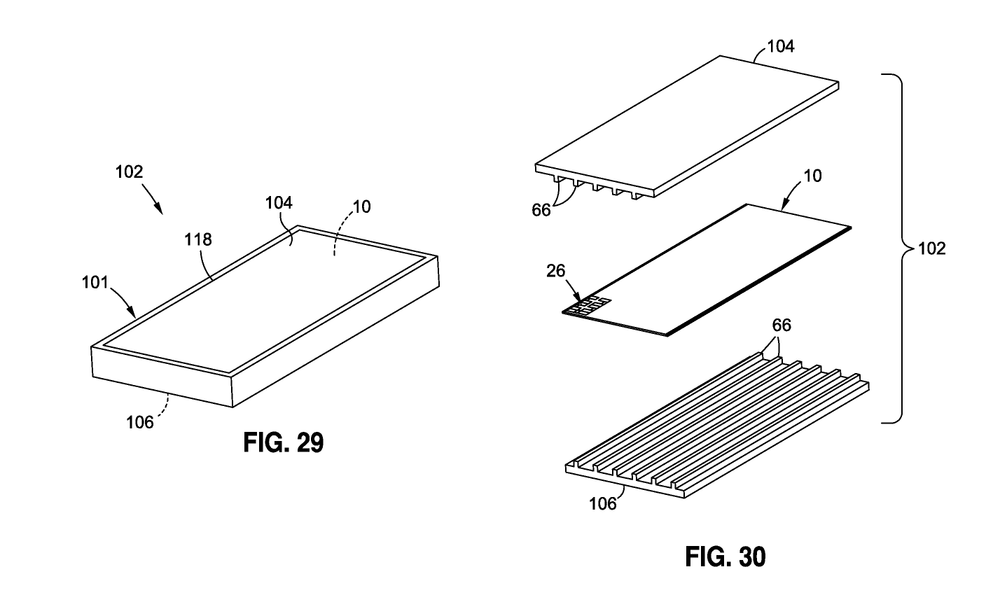

The outer ring 202 and/or the side closeouts 160 and inserts 120 may be formed of high-strength polymeric material such as Nylon™, polycarbonate, and/or polyimide material, and may also comprise fiber-reinforced polymer matrix 138 material such as carbon fiber reinforced plastic of glass fiber reinforced plastic. The perimeter band 101 may also be formed of ceramic material, metallic material, or any combination of polymeric, ceramic, and metallic material. In still other examples, the perimeter band 101 may be a dispensed assembly adhesive 118 applied around the perimeter edges of the top and bottom heat coupling plate 104, 106 and cured or hardened to encapsulate the thermoelectric foil 10, as shown in the embodiment of FIGS. 29-32 and described below. In any one of the thermoelectric generator module 102 embodiments disclosed herein, the head 108 of the top and/or bottom heat coupling plate 104, 106 may protrude beyond the upper and/or lower surfaces 172, 174 of the perimeter band 101 in a manner such that the heads 108 of the heat coupling plates 104, 106 may absorb mechanical forces and thereby avoiding tensile forces 256 and/or shear forces 258 on the thermoelectric foil 10 of the thermoelectric generator module 102.

As mentioned above, the thermoelectric foil 10 may include a substrate 20 which may be formed of an electrically insulating material such as Kapton™ or other electrically insulating material. The thermoelectric foil 10 may be described as a planar thermoelectric foil 10 in reference to the orientation of the thermoelectric legs 26 parallel to the substrate 20 surface. In the present disclosure, the term “planar” is not to be construed as limiting the thermoelectric foil 10 to a planar configuration. In this regard, the thermoelectric foil 10 may have a non-planar shape such a simply-curved shape, a compound curved shape, a contoured shape, or other shape. For example, the thermoelectric foil 10 may have a contoured shape that substantially matches the contour of a wearer's body such as the contour of a wearer's wrist or other body part. The thermoelectric foil 10 may also have a shape that is curved or contoured to substantially match the shape or contour of a matrix or a wearable thermoelectric generator assembly 100 (e.g., a wearable band) configured to convert body heat into electricity such as for powering an electronic device.

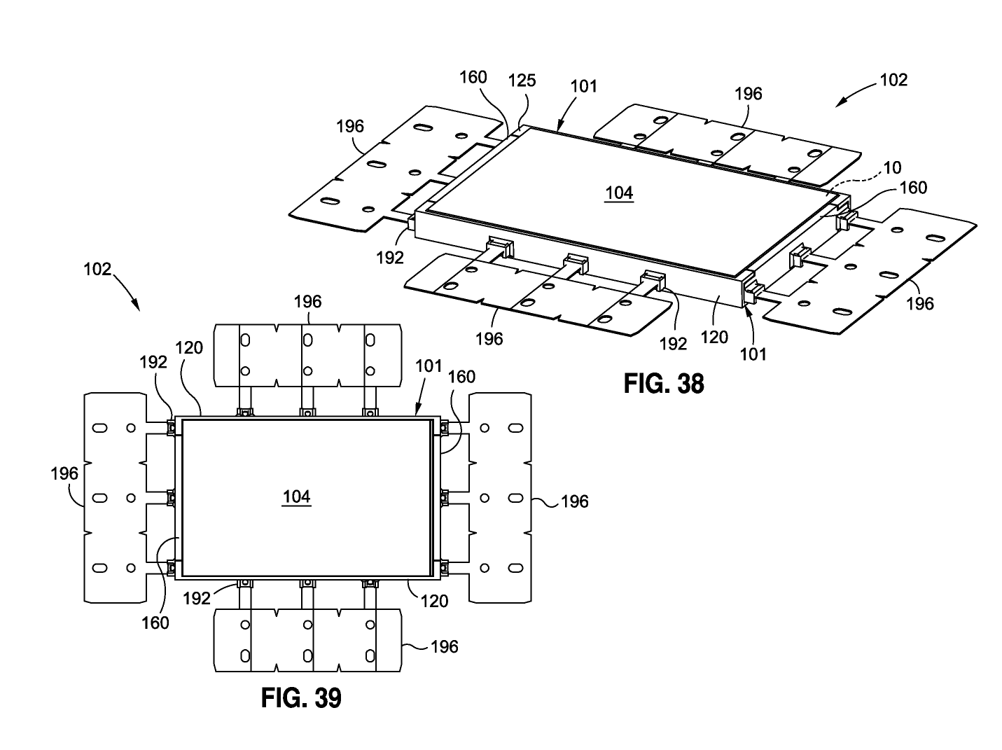

The substrate 20 (FIG. 12, 19) may have a plurality of thermoelectric legs 26 (FIG. 12, 19) formed of alternating dissimilar materials and arranged in one or more rows 60 (FIG. 19) on the upper substrate surface 22 (FIG. 18) and/or on the lower substrate surface 24 (FIG. 18). The thermoelectric legs 26 on the upper substrate surface 22 and/or the lower substrate surface 24 may be electrically connected in series. In some examples, the thermoelectric generator module 102 may include a plurality of thermoelectric foils 10 that which may be arranged in a stacked configuration (not shown) as disclosed in U.S. Patent Publication No. 2011/0094556 to Stark, and/or which may be arranged in a side-by-side configuration as shown in FIGS. 38-42 and described in greater detail below.

As described above and shown in FIGS. 11-12, each one of the thermoelectric legs 26 may define a leg axis 30 extending along a lengthwise direction of the thermoelectric leg 26. The thermoelectric legs 26 may be oriented non-parallel to the row axis 62 and the lengthwise direction of the thermoelectric legs 26 may be parallel to the substrate surfaces 22, 24. The lengthwise direction of each one of the thermoelectric legs 26 may be described as the direction of electrical current flow through the thermoelectric leg 26. Each one of the thermoelectric legs 26 may have opposite lengthwise ends 28. The lengthwise end 28 of each one of the thermoelectric legs 26 may be electrically connected to an adjacent thermoelectric leg 26 at an electrical connection defining a plane that is parallel to the plane of the electrical connection of the opposite lengthwise end 28 of the thermoelectric leg 26 to a different thermoelectric leg 26.

As shown in FIGS. 11-12, the leg ends 28 on one side of each row 60 of thermoelectric legs 26 may be aligned with a thermally conductive strip 66 of the top heat coupling plate 104. The legs ends 28 on the opposite side of each row 60 of thermoelectric legs 26 may be aligned with a thermally conductive strip 66 of the bottom heat coupling plate 106 such that a heat gradient across the top and bottom heat coupling plate 104, 106 causes heat to flow lengthwise through the thermoelectric legs 26 and resulting in the generation of electrical current flowing in series through the thermoelectric legs 26. As described above, the thermally conductive strips 66 may define thermal gaps 68 between the thermoelectric legs 26 and the top and bottom heat coupling plates causing heat to flow lengthwise through each one of the thermoelectric legs 26 along a direction parallel to the substrate surfaces 20 wherein the heat flows from one end of the thermoelectric leg 26 overlapped by a thermally conductive strip 66, to an opposite end of the thermoelectric leg 26 overlapped by a different thermally conductive strip 66. In some examples, the thermoelectric generator module 102 may include at least one electrically insulating layer 70 interposed between and physically separating the thermally conductive strips 66 from the thermoelectric legs 26.

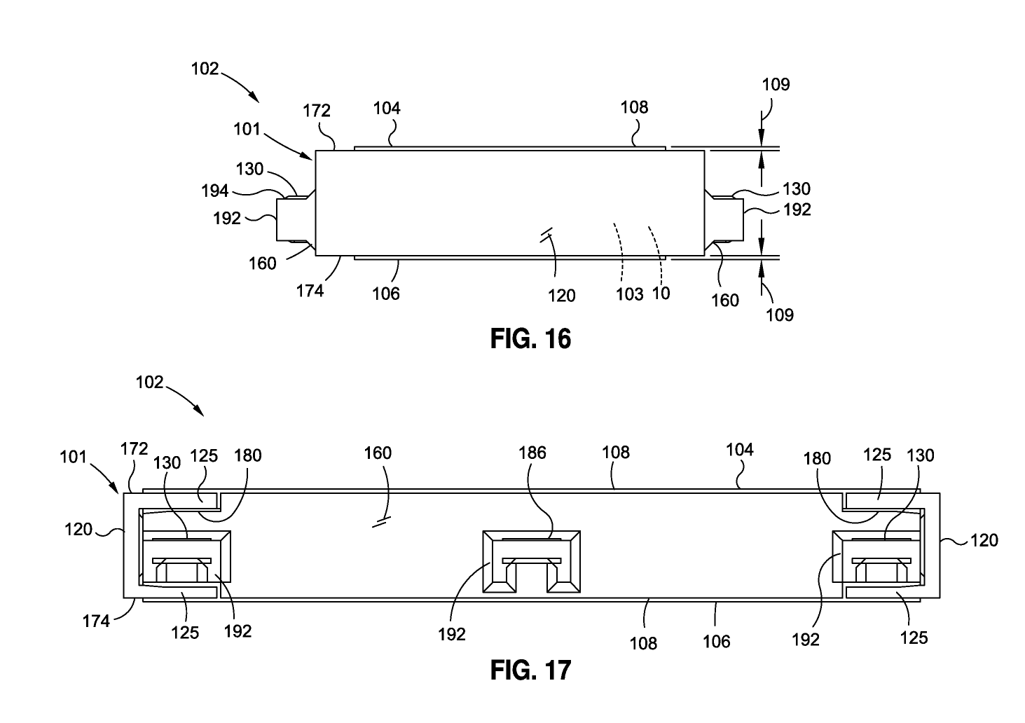

In FIG. 13, shown is an embodiment of the thermoelectric generator module 102 wherein the perimeter band 101 is comprised of a pair of side closeouts 160 mounted on opposite sides of the top and bottom heat coupling plate 104, 106, and a pair of inserts 120 mountable on opposite ends of the top and bottom heat coupling plate 104, 106. The pair of inserts 120 on opposite ends of the top and bottom heat coupling plate 104, 106 may be interconnected to the side closeouts 160. The inserts 120 and the side closeouts have upper and lower surfaces 172, 174 (FIGS. 16-18).

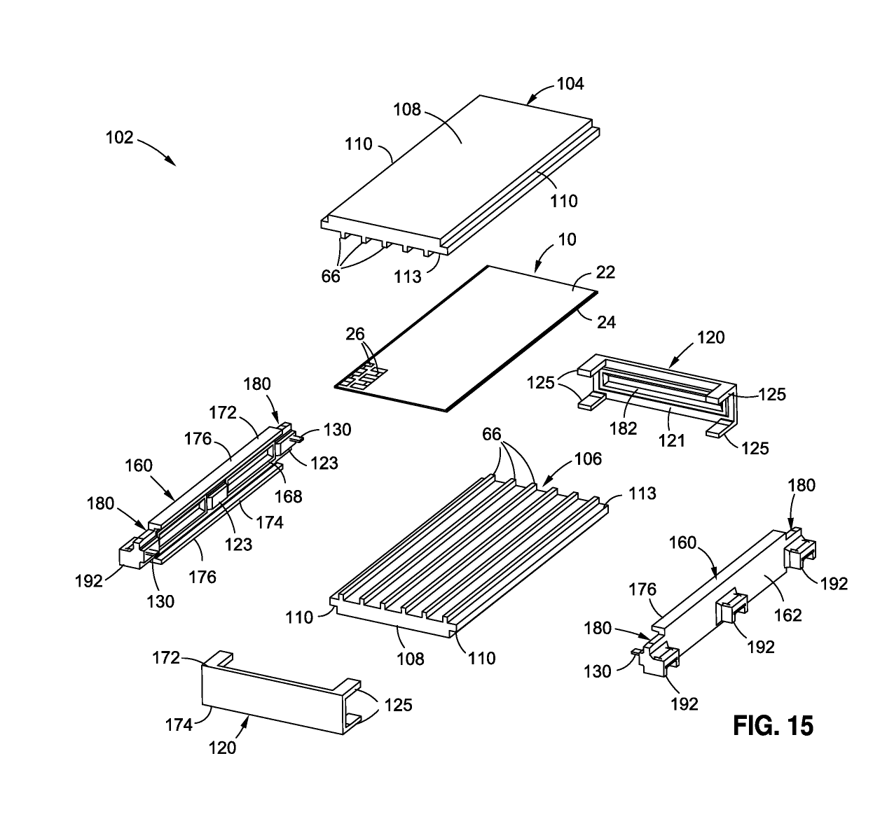

FIG. 14 is a top view of the thermoelectric generator module 102 and illustrating the head 108 of the top heat coupling plate 104 circumscribed by the perimeter band 101 which is comprised of the side closeouts 160 on the sides and the inserts 120 on the ends of the top heat coupling plate 104. As indicated above, the head 108 may be located on a side of the heat coupling plate 104, 106 opposite the thermally conductive strips 66 (FIG. 15) which are formed on an inner surface 113 of each heat coupling plate 104, 106. In some examples, the thermally conductive strips 66 may be integrally formed with the respective top and bottom heat coupling plate 104, 106. However, in other examples, the thermally conductive strips 66 may be separate from the top and/or bottom heat coupling plate 106.

In FIG. 14, although shown as having a generally rectangular shape, the thermoelectric generator module 102 may be provided in any one of a variety of different sizes and shapes, without limitation. For example, the thermoelectric generator module 102 may be provided in a square shape, or in shape that includes rounded sides, or in any other shape. In the embodiment shown, each one of the side closeouts 160 may include one or more support tab 192 protruding laterally outwardly from the side closeouts 160. Although the thermoelectric generator module 102 is shown as having three (3) support tabs 192 protruding from each one of the side closeouts 160, any number of support tabs 192 may be provided. For example, each one of side closeouts 160 may have a single support tab 192. Alternatively, each one of the side closeouts 160 may have a support tab 192 located at the apposing ends of the side closeouts 160.

FIG. 15 is an exploded view of an embodiment of the thermoelectric generator module 102. Shown are the head 108 and the thermally conductive strips 66 of the top heat coupling plate 104. In some embodiments, the top and/or bottom heat coupling plate 104, 106 may include recessed portions 110 extending along opposing sides of the top and/or bottom heat coupling plate 104, 106. The recessed portions 110 may be sized and configured to receive side flanges 176 that may be included on the upper and lower surfaces 172, 174 of the side closeouts 160. Also shown in FIG. 15 are the end inserts 120, each of which may include a plurality of prongs 125 which may protrude from an inner surface 121 of the inserts 120. The prongs 125 may be received within a corresponding set of notches 180 that may be formed in the ends of the upper and lower surfaces 172, 174 of the side closeouts 160.

FIG. 16 is an end view of the thermoelectric generator module 102. The head 108 of the top heat coupling plate 104 and/or the bottom heat coupling plate 106 may be configured such that there is a protrusion 109 above and below the respective upper and/or lower surfaces 172, 174 of the side closeouts 160 and inserts 120. The support tabs 192 protrude outwardly from the side closeouts 160. The support tabs 192 may include lead frames 196 (e.g., see FIG. 38) to facilitate handling of the thermoelectric generator module 102 during the manufacturing and assembly process. The support tabs 192 may include one or more electrical contact clips 130 that extend through the perimeter band 101 (e.g., through the side wall of the side closeouts 160 and the end wall of the inserts 120) and into an interior 103 of the thermoelectric generator module 102. The electrical contact clips 130 may provide a means for electrically connecting the thermoelectric foil 10 to an external load or to an adjacent thermoelectric generator module 102.

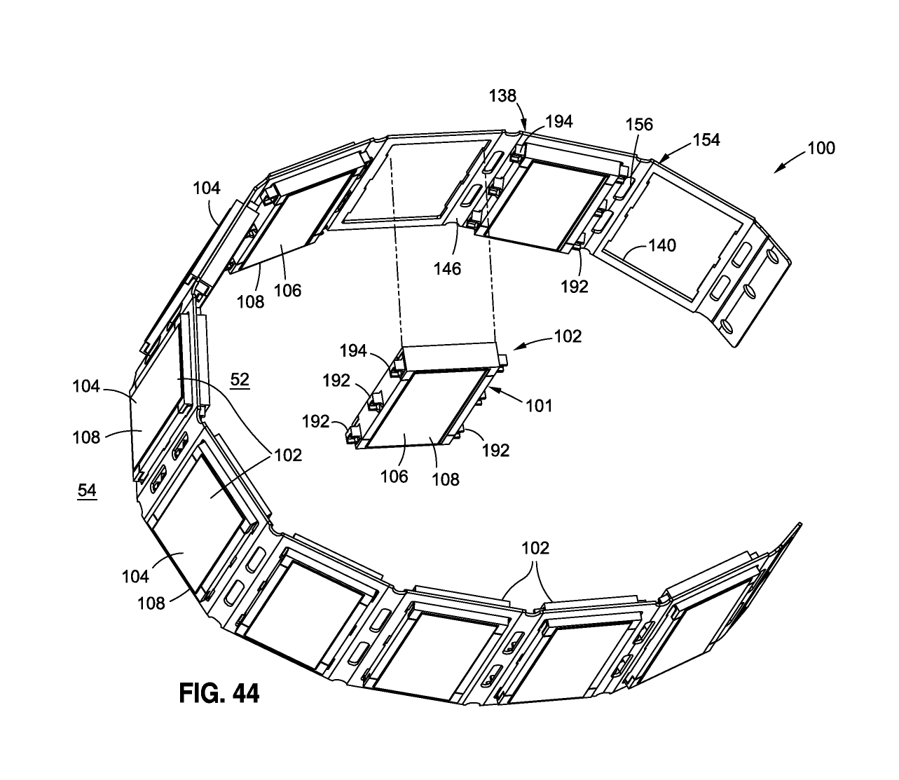

In some examples, the support tabs 192 may provide a means for mounting the thermoelectric generator module 102 to a matrix 138 (FIG. 10, 44) such as to a wearable band (e.g., a wristband, armband, leg end), or other wearable assembly, as described above and below. In this regard, the support tabs 192 may each include a mounting feature 194 such as a mounting surface that may be placed in contacting relation with a matrix 138 after inserting the thermoelectric generator module 102 through an opening 140 formed in the matrix 138 (e.g., see FIG. 44). In some examples, the mounting surface of the support tabs 192 may be located at a height that is below the height of the upper surface 172 of the side closeout 160 and inserts 120, as shown in FIG. 16. The mounting surfaces of the support table 192 may be oriented generally parallel to the surface of the matrix 138 to which the thermoelectric generator module 102 may be mounted.

FIG. 17 is a side view of the thermoelectric generator module 102 and illustrating the protrusion of the head 108 of the top and bottom heat coupling plates 104, 106 extending respectively above and below the upper and lower surfaces 172, 174 of the side closeouts 160 and the inserts 120 (i.e., the perimeter band 101). Also shown in FIG. 17 are the prongs 125 of the inserts 120 which are received within notches 180 formed within the ends of the side closeouts 160. The distance between the facing surfaces each pair of prongs 125 may be complementary to the distance between the recessed portions 110 of the top and bottom heat coupling plate 104, 106. In this regard, the spacing between the facing surfaces of each pair of prongs 125 on each end of each insert 120 is preferably sized such that the prongs 125 fit within the notches 180 and allow for the installation of assembly adhesive 118 between the prongs 125 and the notches 180 for bonding together the inserts 120 to the side closeouts 160.

FIG. 18 is an end view of the thermoelectric generator module 102 with an insert 120 omitted from the end of the thermoelectric generator module 102 to expose the thermoelectric foil 10 captured between the top and bottom heat coupling plate 104, 106. As can be seen, the thermal conductive strips of the top and bottom heat coupling plate 104, 106 are in contact with the respective upper and lower surface of the thermoelectric foil 10. Also shown is an electrical contact clip 130 extending inwardly from the support tab 192 and through the perimeter band 101 (e.g., through the side wall 162 of the side closeouts 160) for electrical connection with the thermoelectric legs 26 (FIG. 19) of the thermoelectric foil 10. A pair of electrical contact clips 130 may be electrically connected to a corresponding pair of metal contacts 76 (FIG. 19) located at opposing ends of a series of thermoelectric legs 26, as shown in FIG. 19 and described above.

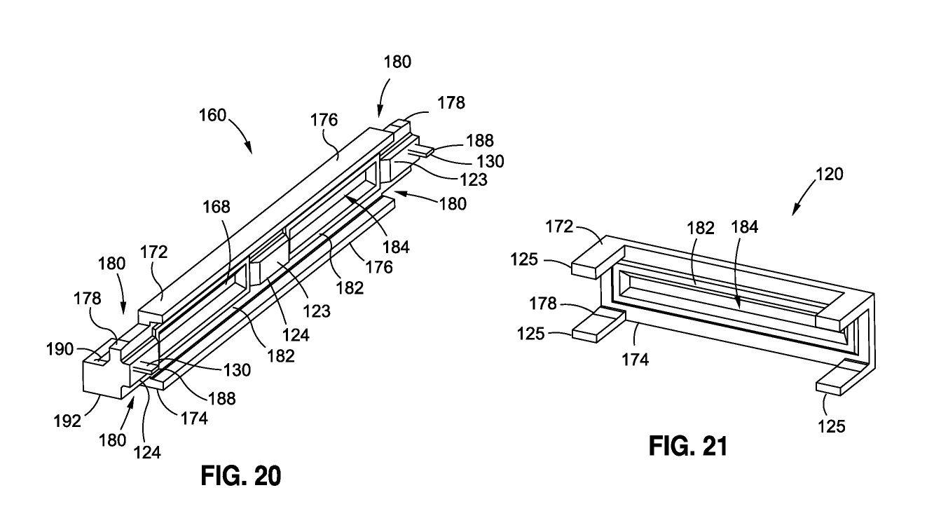

FIG. 18 further illustrates the inner surface 113 of the bottom heat coupling plate 106 in contact with a shelf 123 protruding inwardly from the inner surface of the perimeter band 101 (e.g., side closeouts 160). As shown described in greater detail in FIG. 20, each one of the side closeouts 160 may include one or more shelves 123 locally placed along the inner surface 168 of the side closeout 160. Also shown in FIG. 18 is a notch 180 formed in the upper surface 172 of each side closeout 160 for receiving the upper prongs 125 (FIG. 15) of the insert 120. The prongs 125 may be adhesively bonded to the notches 180. The side closeouts 160 may be adhesively bonded to the side edges of the top and bottom heat coupling plate 104, 106 using an assembly adhesive 118 (FIG. 24) which may mechanically stabilize the assembly of the thermoelectric generator module, and which may also function as a seal 136 (FIG. 24) to protect the thermoelectric foil 10 from moisture, debris, and other environmental elements.

FIG. 18 further illustrates the protrusion of the head 108 of each one of the top and bottom heat coupling plates 104, 160 respectively above and below the respective upper and lower surfaces 172, 174 of the side closeouts 160 and inserts 120. As indicated above, the protruding head 108 on the top heat coupling plate 104 and/or bottom heat coupling plate 106 may advantageously reduce or avoid the imposition of compressive forces 254, tensile forces 256, and/or shear forces 258 on the thermoelectric generator module 102 as result of contact or impact of the thermoelectric generator module 102 against an external surface such as a hard surface. For example, compressive forces 254 may undesirably compromise the integrity of the electrical connections between the series of thermoelectric legs 26. Tensile forces 256 may undesirably urge the top and bottom heat coupling plate 104, 106 away from one another compromising thermal coupling between the heat coupling plates and the thermoelectric foil 10. Shear forces 258 may undesirably cause the lateral displacement of the top and bottom heat coupling plates relative to one another which may compromise the alignment of the leg ends 28 with the thermally conductive strips 66. In this regard, the arrangement of the side closeouts 160 and inserts 120 circumscribing the perimeter of the top and bottom heat coupling plate 104, 106 may advantageously minimize disruptions in the thermal connections and/or electrical connections within the thermoelectric generator module 102.

FIG. 19 is a top view of the thermoelectric generator module 102 with the top heat coupling plate 104 removed to expose an arrangement of thermoelectric legs 26 of the thermoelectric foil 10. The thermoelectric legs 26 may be arranged in a meandering pattern on the substrate 20 and generally aligned in rows 60 along the thermoelectric foil 10. The thermoelectric legs 26 may terminate at metal contacts 76 on opposite sides of the thermoelectric foil 10, such as at the lower edge of the module 102 in FIG. 19. The electrical contact clips 130 may extend through the perimeter band 101 and protrude inwardly into the interior 103 of the thermoelectric generator module 102 and may contact the metal contacts 76 of the thermoelectric legs 26:

FIG. 20 is a perspective view of an example of a side closeout 160 that may be mounted on each one of opposing sides of the thermoelectric generator module 102. The side closeout 160 may include upper and lower side flanges 176 extending along the sides of the side closeout 160. Also shown are notches 180 formed on the upper and lower surfaces 172, 174 on each end of the side closeout 160. The notches 180 on the upper surface 172 of the side flange 176 may include a ramped surface 178 to facilitate installation of the prongs 125 of the inserts 120 into the notches 180. Also shown in FIG. 20 are internal clip portions 188 of the electrical contact clips 130 extending inwardly through the side closeout 160. As indicated above, one or more of the support tabs 192 may include a clip (e.g., a mechanical clip or an electrical contact clip) which may be formed of metallic material or non-metallic material, and which may be molded into the support tabs 192. Although the side closeout 160 in FIG. 20 is shown having a pair of electrical contact clips 130 on each of the opposing ends of the side closeout 160, the side closeout 160 may include only a single electrical contact clip 130 at one end for electrical connection with one end of a series of thermoelectric legs 26 of the thermoelectric foil 10. The side closeout 160 on the opposite side of the thermoelectric generator module 102 may also include an electrical contact clip 130 for electrical connection to an opposite end of the series of thermoelectric legs 26.

FIG. 20 further illustrates a plurality of shelves 123 which may be locally formed on the inner surface 168 of the side closeout 160. Each one of the shelves 123 may include a lower shelf surface 124 against which the inner surface 113 of the bottom heat coupling plate 106 may be placed into contact as a means to index the position of the bottom heat coupling plate 106 relative to the side closeout 160, and to mechanically stabilize the top and/or bottom heat coupling plate 106 against compressive forces on the top and/or bottom heat coupling plate 104, 106. In addition, each one side closeouts 160 may include spacer portions 182 protruding from an inner surface 168 of the side closeout 160 and extending in a longitudinal direction and/or vertical direction along the inner surface 168 of the side closeout 160. The spacer portions 182 may be placed in contact with at least a portion of a side edge of both the top and bottom heat coupling plate 104, 106. The spacer portions 182 may be sized and configured such that when the spacer portions 182 of both side closeouts 160 are in contact with the side edges of the top and bottom heat coupling plate 104, 106, side-to-side displacement of the top and bottom heat coupling plate 104, 106 in a lateral direction 250 (FIG. 14) relative to one another is prevented. The spacer portions 182 may form rectangular shapes on the inner surface 168 of the side closeout 160 and may circumscribe areas of reduced thickness of the side closeout 160 and which may be described as inner grooves 184 formed in the inner surface 168 of the side closeout 160. The areas of reduced thickness in the side closeout 160 may minimize the shunting of heat flow through the side closeout 160.

FIG. 21 is a perspective view of an example of an insert 120 that may be mounted on an end of the thermoelectric generator module 102. As indicated above, the insert 120 may include a pair of prongs 125 on each end of the insert 120. One or more of the facing surfaces of each pair of prongs 125 may include a ramped surface 178 to facilitate installation of the prong 125 into the side closeout 160 notches 180 and onto the recessed portions 110 of the top and bottom heat coupling plate 104, 106. As indicated above, the facing surfaces of each pair of prongs 125 may be spaced apart at a distance that is complementary to the distance between the recessed portions 110 of the top and bottom heat coupling plate 104, 106 such that the prongs 125 facilitate clamping together of the top and bottom heat coupling plates to provide continuous thermal coupling of the thermoelectric foil 10 with the thermally conductive strips 66 of the top and bottom heat coupling plate 104, 106.

In FIG. 21, the inner surface 121 of each one of the inserts 120 may also include spacer portions 182 similar to the spacer portions 182 described above for the side closeouts 160. The spacer portions 182 may bear against the end edges of the top and bottom heat coupling plates 104, 106. The spacer portions 182 may be sized and configured such that when the spacer portions 182 of both of the inserts 120 are in contact with the top and bottom heat coupling plate 104, 106, displacement of the top and bottom heat coupling plate 104, 106 in a longitudinal direction 252 (FIG. 14) relative to one another is prevented. In some examples, an end barrier 260 (FIG. 28) may be installed over each end of the top and bottom heat coupling plate 104, 106 to provide a barrier against assembly adhesive 118 that may be installed to bond the inserts 120 to the notches 180 in the side closeouts 160 and the recessed portion 110 of the top and bottom heat coupling plate 104, 106. The end barrier 260 on each end of the top and bottom heat coupling plate 104, 106 may prevent assembly adhesive 118 from flowing into the thermal gaps 68 between thermally conductive strips 66.

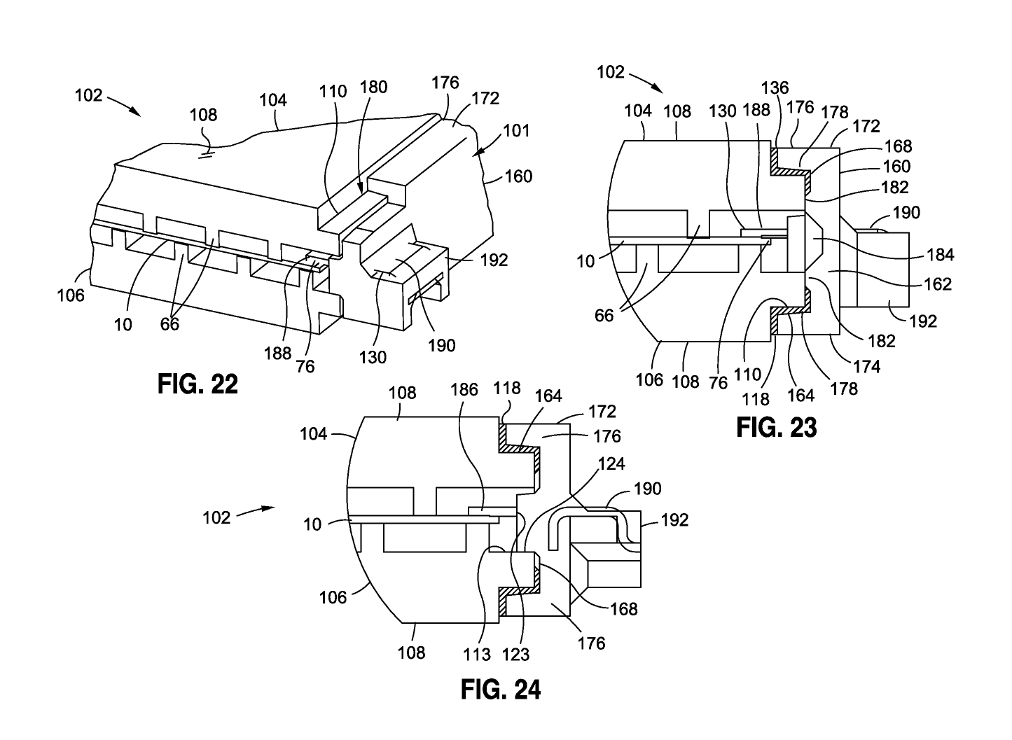

FIG. 22 shows a corner of the thermoelectric generator module 102 illustrating an electrical contact clip 130 electrically connected to a metal contact 76 on an end of a series of thermoelectric legs 26. As indicated above, in some examples, one or more of the support tabs 192 may include a clip which may be configured as an electrical contact clip 130 or as a mechanical clip 186. Each clip may be molded into the support tabs 192. In some examples, the clip may have a non-straight shape to lock the clip into the support tab 192 and prevent movement of the clip relative to the support tab 192. In the example shown, the clip may be configured as an electrical contact clip 130 and may have an internal clip portion 188 that has a reduced width that is sized complimentary to the relatively small width of the metal contact 76 on the thermoelectric foil 10.

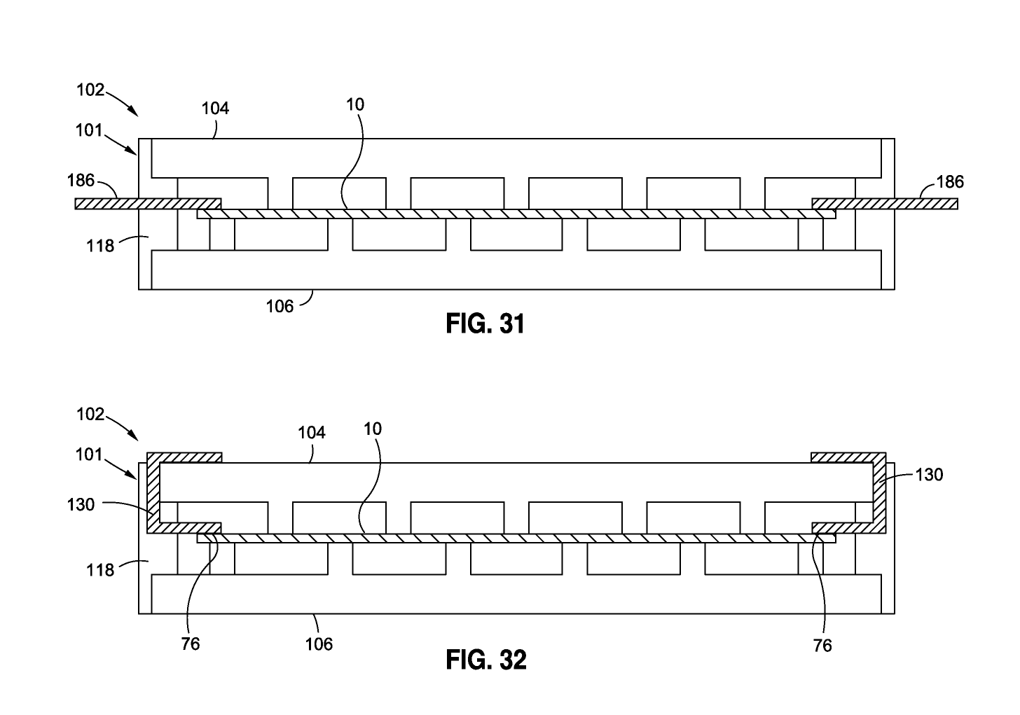

In other examples, the clip may be configured as a mechanical clip 186 (FIG. 31) that may extend through the perimeter band 101 (e.g., through the side closeout 160) and may non-electrically contact the thermoelectric foil 10. In this regard, the mechanical clip 186 may rest against the upper surface of the thermoelectric foil 10 and may clamp the thermoelectric foil 10 against the bottom heat coupling plate 106 to mechanically stabilize the foil 10 against vertical displacement relative to the bottom heat coupling plate 106. FIG. 22 shows a notch 180 formed in the side closeout 160 at a level below the level of the recessed portion 110 of the top heat coupling plate 104. As indicated above, the prongs 125 may fit within the notches 180 and may be adhesively bonded to the notches 180 to interconnect the inserts 120 to the side closeouts 160.

FIG. 23 shows a sectional view of the thermoelectric generator module 102 illustrating the mounting of the side closeouts 160 to the top and bottom heat coupling plate 104, 106. As indicated above, each one of the side closeouts 160 may include one or more spacer portions 182 that may be sized and configured to contact the side edges of the top and bottom heat coupling plate 104, 106. The spacer portions 182 may define an inner groove 184 formed between the spacer portions 182 and representing a thinned area of the side wall 162 of the side closeout 160 to increase the thermal resistance of the side closeout 160. The side closeout 160 may include the upper and lower side flanges 176, each of which may include facing surfaces. In some examples, the facing surfaces of the upper and lower side flanges 176 may be formed as ramped surfaces 178 to facilitate assembly of the side closeout 160 with the top and bottom heat coupling plate 104, 106.

The side closeouts 160 may each be configured such that only the spacer portions 182 are in direct contact with the side edges of the top and bottom heat coupling plate 104, 106. The spacer portions 182 may be bonded to the side edges of the top and bottom heat coupling plate 104, 106. The gap 164 between the side flanges 176 and the top and bottom heat coupling plate 104, 106 may be filled with an assembly adhesive 118 which preferably has a relatively low thermal conductivity. As indicated above, the assembly adhesive 118 may bond the side closeouts 160 and/or the inserts 120 to the top and bottom heat coupling plates and may form an environmental seal 136 for protecting the thermoelectric foil 10 encapsulated within the interior 103 of the thermoelectric generator module 102.

FIG. 24 is another sectional view of the thermoelectric generator module 102 illustrating a shelf 123 protruding inwardly from the inner surface 168 of the side closeout 160. As indicated above, the shelf 123 may include a shelf surface 124 against which the inner surface 113 of the bottom heat coupling plate 106 may be placed into contact for mechanically stabilizing the top and bottom heat coupling plate 104, 106 against vertical displacement relative to one another. The inner surface 113 of the top heat coupling plate 106 may be placed in spaced relation to the shelf 123. Alternatively, the inner surface 113 of the top heat coupling plate 104 may contact the shelf surface 124, and the inner surface of the bottom heat coupling plate 106 may be placed in spaced relation to the shelf 123.

FIG. 24 further illustrates a non-straight shape or serpentine shape of an external clip portion 190 of the clip that may be molded into the support tab 192. A portion of the molded-in clip may be exposed to facilitate electrical connection of the thermoelectric foil 10 to a load or to an adjacent thermoelectric generator module, as indicated above. In the example shown, the exposed portion of the clip may be positioned along the mounting surface of the support tabs 192 such that when the thermoelectric generator module 102 is mounted within an opening 140 of a wearable thermoelectric generator assembly 100 (FIG. 44), the exposed portion of the clip may contact a printed circuit 146 that may be applied to the wearable thermoelectric generator assembly 100, as described below.

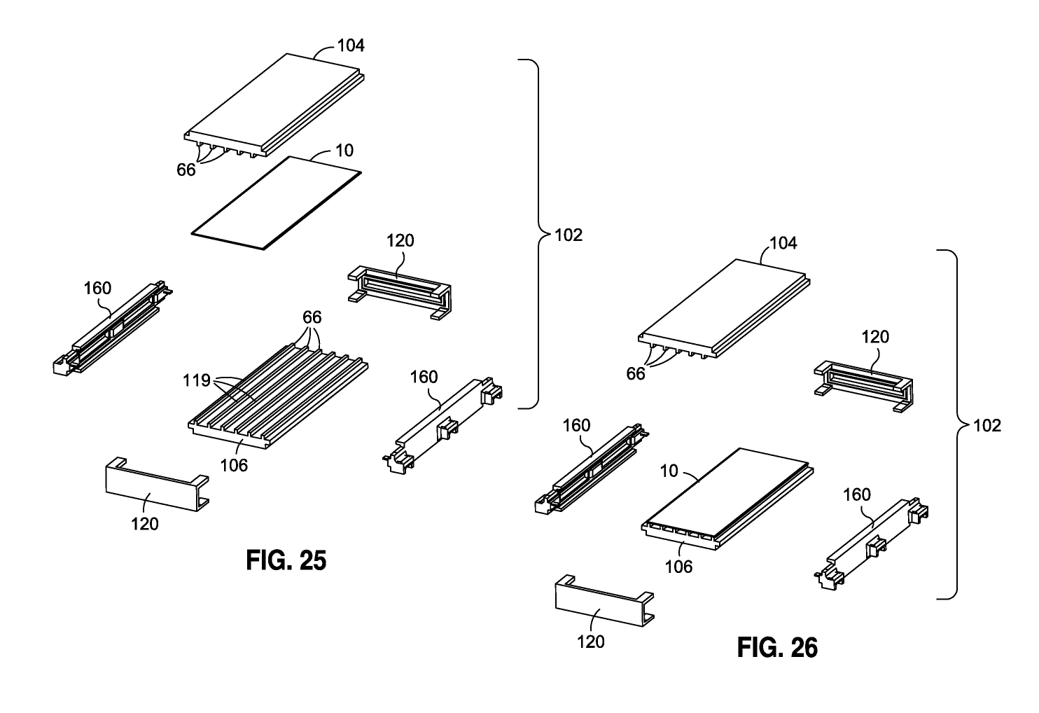

FIG. 25-28 illustrate a sequence of assembling the embodiment of the thermoelectric generator module 102 shown in FIGS. 13-24. FIG. 25 is an exploded view of the thermoelectric generator module 102 showing the optional application of thermally conductive adhesive 119 to the top surfaces of the thermally conductive strips 66 of the bottom heat coupling plate 106. Such thermally conductive adhesive 119 may improve thermal coupling of the bottom heat coupling plate 106 with the ends of the thermoelectric legs 26 on the thermoelectric foil 10. FIG. 26 shows a next step in the sequence of assembling the thermoelectric generator module, including assembling the thermoelectric foil 10 with the bottom heat coupling plate 106 after application of the thermally conductive adhesive 119.

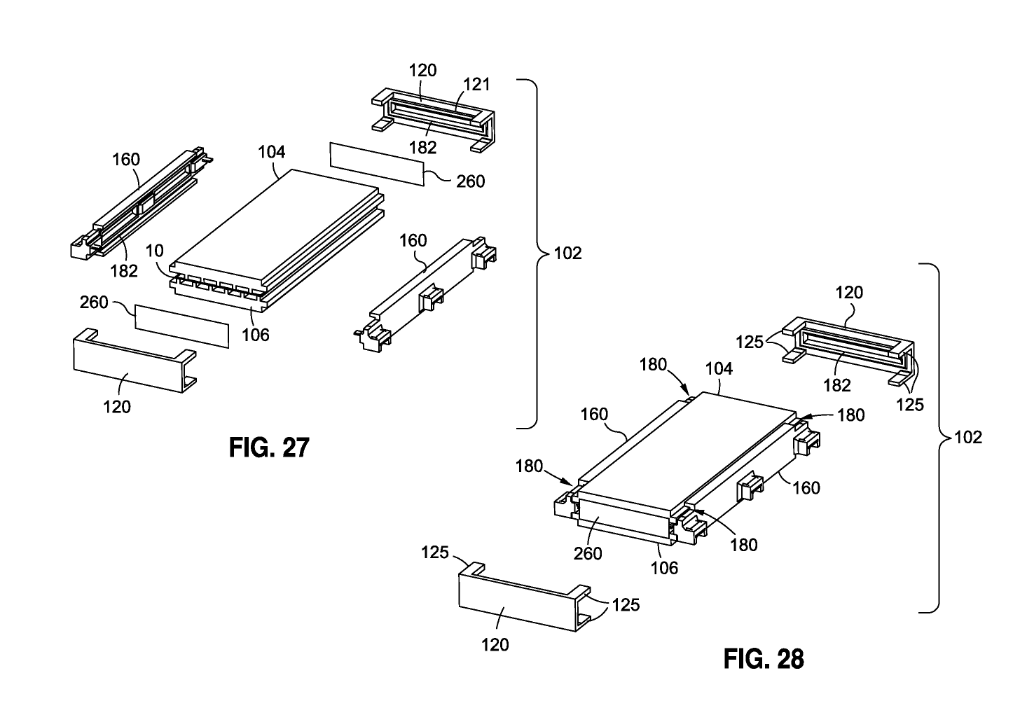

FIG. 27 shows the top heat coupling plate 104 assembled to the thermoelectric foil 10 and further illustrating a pair of end barriers 260 (e.g., tape, plastic sheeting strips, etc.) on opposing ends of the thermoelectric generator module 102. As indicated above, the end barriers 260 may prevent contact between assembly adhesive 118 later applied to the inserts 120 and the thermally conductive strips 66 of the top and bottom heat coupling plates 104, 106. In some examples, the end barriers 260 may be sized and configured such that the end edges of the top and bottom heat coupling plate 104, 106 are exposed to allow the assembly adhesive 118 to bond the inner surface 121 of the inserts 120 to the end edges. The end barrier 260 may extend vertically across the gap between the top and bottom heat coupling plate 104, 106 and may cover the ends of the thermally conductive strips 66 of the top and bottom heat coupling plate 104, 106 as a means to prevent exposure of the thermally conductive strips 66 to the assembly adhesive 118 which may otherwise cause the assembly adhesive 118 to be wicked into the thermal gaps 68 between the thermally conductive strips 66.

FIG. 28 shows the assembly of the side closeouts 160 to the side edges of the top and bottom heat coupling plate 104, 106. As indicated above, assembly adhesive 118 may be used to bond the spacer portions 182 (FIG. 20) to the top and bottom heat coupling plate 104, 106. The end barriers 260 may be installed over the ends of the thermally conductive strips 66 of the top and bottom heat coupling plate 104, 106 prior to assembly of the inserts 120 onto the ends of the thermoelectric generator module 102. As described above, the prongs 125 of the inserts 120 may be received within the notches 180 formed in the opposing ends on the upper and lower sides of the side closeouts 160. Assembly adhesive 118 such as epoxy may be used to bond the exposed inner surfaces 121 of the inserts 120 to the end edges of the top and bottom heat coupling plate 104, 106. The assembly adhesive 118 may also bond the prongs 125 to the notches 180 and to the recessed portion 110 of the top and bottom heat coupling plate 104, 106. The final assembled thermoelectric generator module 102 is shown in FIG. 13.

FIG. 29 is a perspective view of a further embodiment of a thermoelectric generator module 102 wherein the perimeter band 101 may be formed by applying assembly adhesive 118 along the perimeter edges of the top and bottom heat coupling plate 104, 106, after which the assembly adhesive 118 may be allowed to cure or harden and thereby encapsulate the thermoelectric foil 10. FIG. 30 is an exploded perspective view of the top and bottom heat coupling plate 104, 106 and the thermoelectric foil 10 that make up the thermoelectric generator module 102 shown in FIG. 29. In FIGS. 29-30, the thermoelectric generator module 102 embodiment may be manufactured by using a temporary holding fixture (not shown) and/or a mold (not shown) for alignment and assembly of the top and bottom heat coupling plates 104, 106 with the thermoelectric foil 10 during application of the assembly adhesive 118. In some embodiments, assembly adhesive 118 such as epoxy may be dispensed along the side edges and end edges, and/or the epoxy may be applied via a pin transfer process or an adhesive injection process. During stages of the assembly process, the assembly adhesive 118 may be allowed to at least partially cure to increase the viscosity of the assembly adhesive 118 and thereby avoid the assembly adhesive 118 flowing out of the perimeter edges.

With the thermally conductive strips 66 of the top and bottom heat coupling plates 104, 106 aligned with the ends of the thermoelectric legs 26 of the thermoelectric foil 10, the assembly adhesive 118 may be allowed to fully cure into a hardened state to form a high-strength perimeter band 101 that provides compressive and tensile strength to the mated top and bottom heat coupling plate 104, 106. The cured assembly adhesive 118 may mechanically stabilize and permanently couple the top and bottom heat coupling plate 104, 106 together in a manner preventing relative movement of the top and bottom heat coupling plate 104, 106 and thermoelectric foil 10 along a lateral direction 250 (FIG. 14), a longitudinal action 252 (FIG. 14), and a vertical direction. In this regard, the arrangement shown in FIG. 29 may provide resistance of the thermoelectric generator module 102 to compressive 254, tensile 256, and/or shear forces 258 (FIG. 18) imposed on the thermoelectric generator module 102.

FIG. 31 is a schematic sectional view of the embodiment of the thermoelectric generator module 102 of FIGS. 29-30, and illustrating an embodiment the top and bottom heat coupling plates 104, 106 adhesively bonded together using the assembly adhesive 118 which forms the perimeter band 101. Also shown is a pair of clips extending through the hardened assembly adhesive 118 on opposing sides of the thermoelectric generator module 102. The clips may be configured as mechanical clips 186 for mechanically stabilizing the thermoelectric foil 10 relative to the top and bottom heat coupling plate 104, 106. The mechanical clips 186 may be located at a generally central location midway between the apposing ends of the thermoelectric generator module 102. However, the mechanical clips 186 may be located at any location along the length of the thermoelectric tenor module 102. The clips may also be configured as electrical contact clips 130 for electrically connecting the thermoelectric legs 26 of the thermoelectric foil 10 to an external load or to another thermoelectric generator module 102.

FIG. 32 is a schematic sectional view of a further embodiment of the thermoelectric generator module 102 of FIGS. 29-30 having a pair of electrical contact clips 130 extended through assembly adhesive 118 on opposite sides of the module 102. The electrical contact clips 130 may extend from the metal contacts 76 of the thermoelectric foil 10 and through the hardened assembly adhesive 118 and may be oriented upwardly along the side edges of the top heat coupling plate 104. In the embodiment shown, the electrical contact clip 130 may wrap over the upper surface of the top heat coupling plate 104 to provide a readily accessible means for electrical connecting the thermoelectric generator module 102 to a load or to another thermoelectric generator module 102.

FIG. 33 is a perspective view of a further embodiment of a thermoelectric generator module 102 wherein the perimeter band 101 is formed as an outer ring 202 having a unitary structure. The outer ring 202 may be formed of a high-strength material such as polymeric material, ceramic material, or metallic material, or any combination of materials. The outer ring 202 may be sized and complementary to the geometric outline of the top and bottom heat coupling plate 104, 106. The outer ring 202 may be bonded to the side edges and end edges of the top and bottom heat coupling plate 104, 106. In some examples, the inner surface of the outer ring 202 may include features such as shelves 123 and spacer portions 182 (e.g., see FIGS. 20-24) to mechanically stabilize the top and bottom heat coupling plate 104, 106 and thermoelectric foil 10 against displacement. In addition, the outer ring 202 may act as an environmental seal 136 for protecting the thermoelectric foil 10 from the elements.

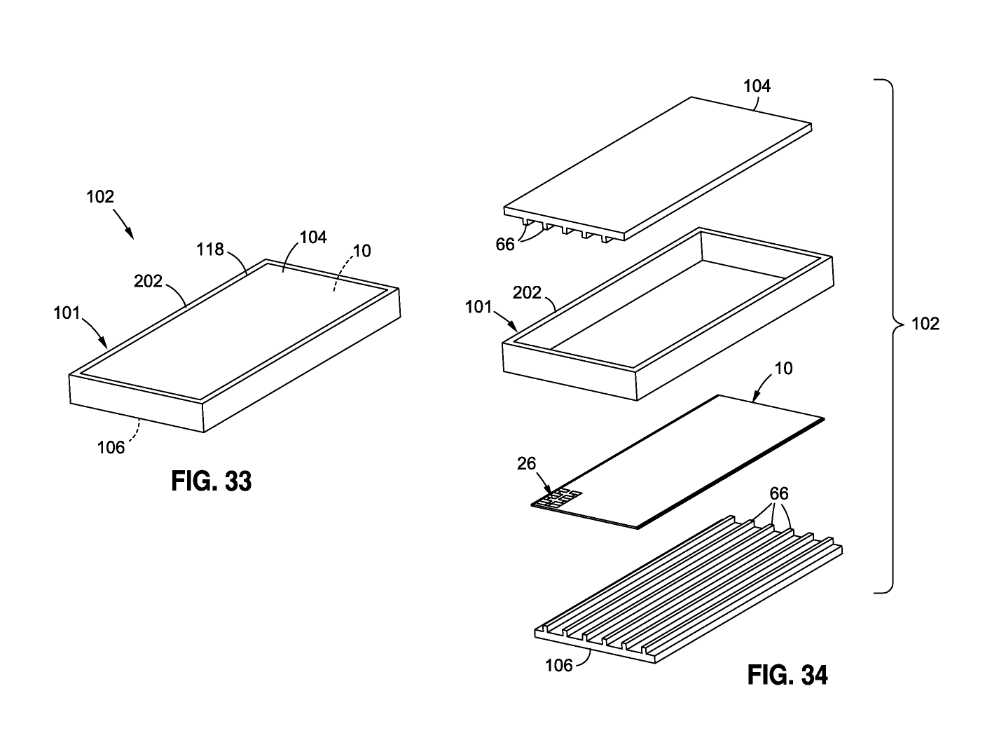

FIG. 34 is a perspective exploded view of the embodiment of the thermoelectric generator module 102 shown in FIG. 33, and illustrating the one-piece construction of the outer ring 202. As indicated above, the outer ring 202 may be assembled with the top and bottom heat coupling plate 104, 106 with the thermoelectric foil 10 sandwiched therebetween. The outer ring 202 may include provisions for electrical connection of the thermoelectric foil 10 to a load or to another thermoelectric generator module 102. For example, electrical contact clips 130 may be molded into the outer wall. The outer ring 202 may also include one or more support tabs 192 (not shown) and/or lead frames 196 (e.g. see FIGS. 38-39) positioned along one or more sides of the outer ring 202 to facilitate handling of the thermoelectric generator module 102 during assembly.

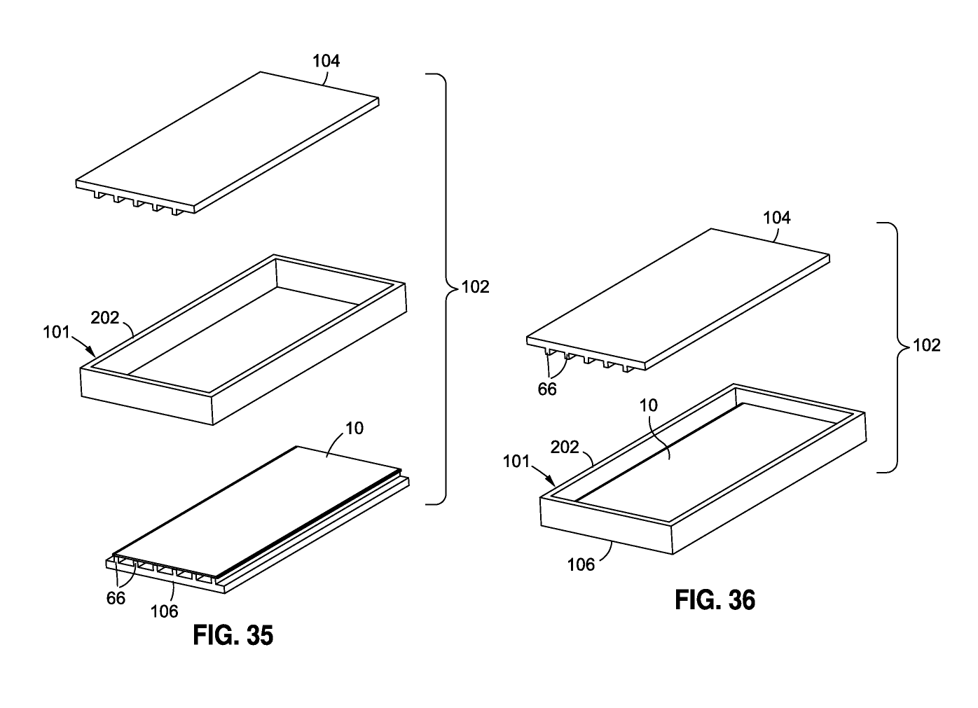

Referring to FIGS. 35-36, the assembly of the thermoelectric generator module 102 of FIG. 33 may include stacking the thermoelectric foil 10 onto the bottom heat coupling plate 106 such that the appropriate leg ends 28 are aligned with the thermally conductive strips 66 of the bottom heat coupling plate 106. In FIG. 36, the outer ring 202 may then be assembled to the bottom heat coupling plate 106/thermoelectric foil 10. The outer ring 202 may include the above-mentioned electrical contact clips 130 which may be molded into the outer ring 202 and positioned such that the electrical contact clips 130 are aligned with metal contacts 76 on the end of a series of thermoelectric legs 26. Assembly adhesive 118 may be applied to the side edges and end edges of the bottom heat coupling plate 106 for bonding to the outer ring 202. The top heat coupling plate 104 may be installed into the outer ring 202 such that the thermoelectric legs 26 of the thermoelectric foil 10 are aligned with the thermally conductive strips 66 of the top heat coupling plate 104. Assembly adhesive 118 may be applied along the side edges and end edges prior to assembly of the top heat coupling plate 104 with the outer ring 202.

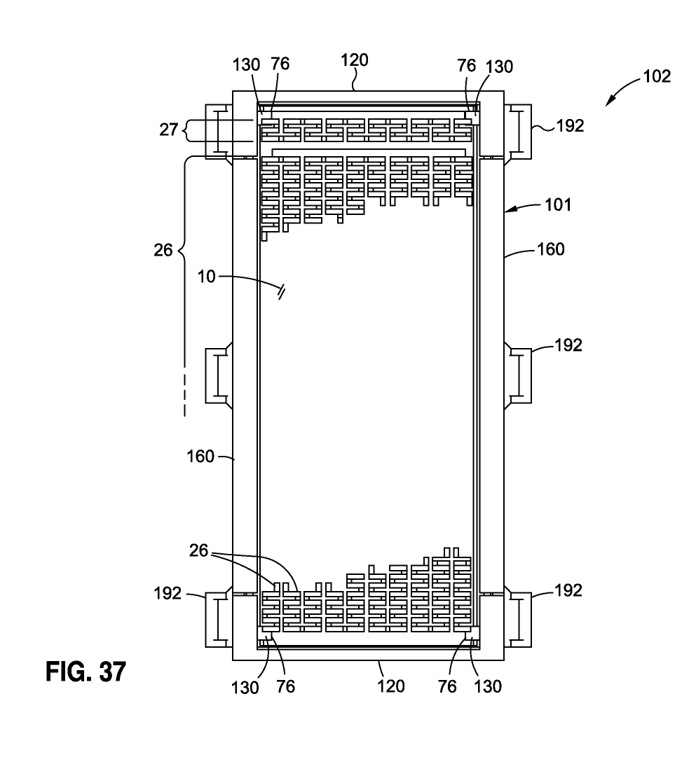

FIG. 37 is a top view of an embodiment of a thermoelectric generator module 102 with the top heat coupling plate 104 removed to show the thermoelectric foil 10. As can be seen, a relatively small quantity of thermoelectric legs 26 may be electrically isolated from the remaining thermoelectric legs 26 which may make up the thermoelectric generator portion (e.g., the power-generating portion) of the thermoelectric generator module 102. The small quantity of electrically-isolated thermoelectric legs 27 may form part of a sensor (e.g., heat flux, temperature, etc.) to facilitate management of the power generation of the thermoelectric generator portion of the thermoelectric legs 26. The ends of the series of electrically-isolated thermoelectric legs 27 may terminate at a pair of metal contacts 76 which may be electrically connected by electrical contact clips 130 extended to the support tabs 192 on the upper end of the thermoelectric generator module 102 shown in FIG. 37.

FIG. 38 is a perspective view of a multi-foil embodiment of a thermoelectric generator module 102 which may contain two (2) or more thermoelectric foils 10 in side-by-side arrangement. FIG. 39 is a top view of the multi-foil embodiment of the thermoelectric generator. The thermoelectric generator module 102 may be configured similar to the embodiment shown in FIGS. 13-24 in the sense that the thermoelectric generator module 102 shown in FIGS. 28-39 may include a perimeter band 101 that may be collectively formed by side closeouts 160 and end inserts 120 extending around the perimeter of the top and bottom heat coupling plates 104, 106 to encapsulate the thermoelectric foil 10. In addition, in FIGS. 38-39, the inserts 120 may optionally include one or more support tabs 192 protruding from the exterior side of each insert 120. Alternatively, the perimeter band 102 of the multi-foil thermoelectric generator module 102 may by formed as hardened assembly adhesive (e.g., see FIGS. 29-32), or as a unitary outer ring 202 (e.g., see FIGS. 33-36).

In some examples, the thermoelectric generator module 102 may have lead frames 196 attached to the support tabs 192 during the manufacturing process. The lead frames 196 may be extensions of the clips that may be molded into the support tabs 192. The lead frames 196 may facilitate handling of the thermoelectric generator module 102 during the assembly process. Upon completion of the assembly process, the lead frames 196 may be physically separated from the support tabs 192.

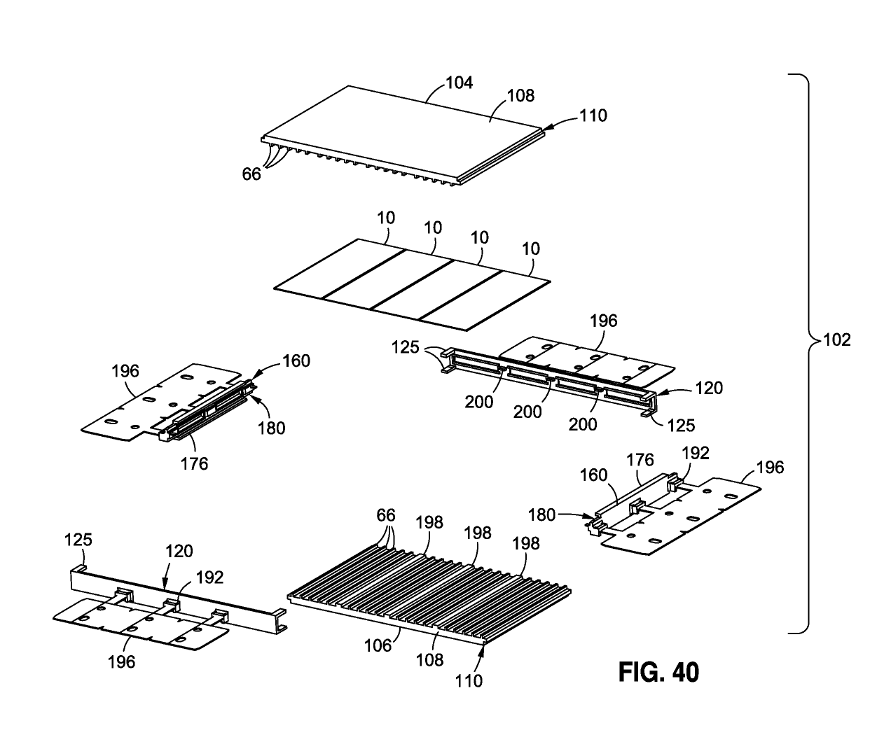

FIG. 40 is an exploded perspective view of the multi-foil thermoelectric generator module 102 of FIG. 38. In the embodiment shown, the thermoelectric generator module 102 contains four (4) thermoelectric foil 10 assemblies mounted in side-by-side relation to one another. However, the thermoelectric generator module 102 may be provided with any number of thermoelectric foils 10 arranged in side-by-side relationship to one another. In some examples, each one of the thermoelectric foils 10 may be substantial duplicates of one another to simplify integration into the thermoelectric generator module, and to reduce manufacturing costs. In some examples, the adjacent thermoelectric foils 10 may be electrically connected in series. In other examples, two (2) or more of the thermoelectric foils 10 may be electrically connected in parallel.

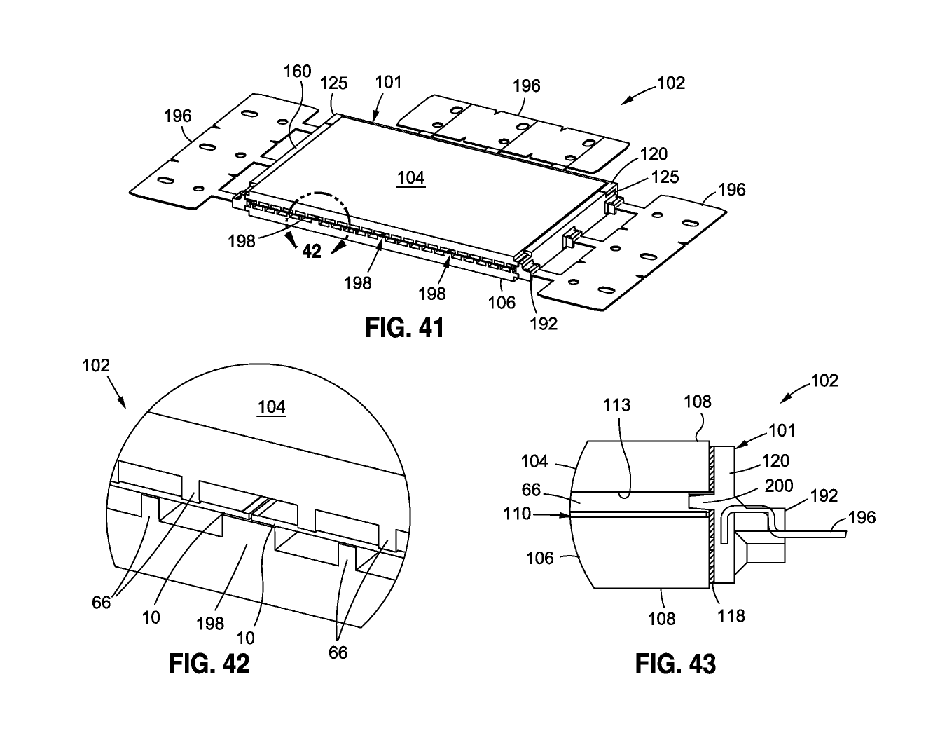

FIG. 41 is a perspective view of the multi-foil thermoelectric generator module 102 of FIG. 38 with an insert 120 removed from an end of the module 102 to illustrate one or more structural support strips 198 that may be formed along the inner surface 113 of the bottom heat coupling plate 106 for supporting adjacent pairs of thermoelectric foils 10. FIG. 42 is an enlarged view of an end of the multi-foil thermoelectric generator module 102 showing an increased width of the structural support strips 198 relative to the width of the thermally conductive strips 66 of the bottom heat coupling plate 106. In this regard, the structural support strips 198 may be wider than the thermally conductive strips 66 to allow each one of the structural support strips 198 to mechanically (e.g. vertically) support the side edges of the adjacent thermoelectric foils 10, and to thermally couple the bottom heat coupling plate 106 to the thermoelectric legs 26 of the adjacent thermoelectric foils 10.

FIG. 43 is a sectional side view of the multi-foil thermoelectric generator module 102 illustrating a finger 200 protruding inwardly from an inner surface 121 of the insert 120. The finger 200 may be located at a position that is complementary to the location of a support tab 192 on an exterior side of the insert 120. However, any number of fingers 200 may be located anywhere along the length of the insert 120. In some examples, each finger 200 may be positioned in alignment with a structural support strip 198 of the bottom heat coupling plate 106. The fingers 200 may be configured to mechanically stabilize and support the top heat coupling plate 104 against compressive force 254. In this regard, the fingers 200 may prevent excessive bowing of the top and/or bottom heat coupling plate 106 under a vertical load that may be imposed against the top and/or bottom heat coupling plate 106.

FIG. 44 shows a partially exploded view of an embodiment of a wearable band 154 of a wearable thermoelectric generator assembly 100. The wearable band 154 may include a plurality of thermoelectric generator modules 102 mountable in a corresponding set of openings 140 formed in the wearable band 154. The openings 140 in the wearable band 154 may be sized complementary to an outer geometry of the thermoelectric generator modules 102. In some examples, the wearable band 154 may include a printed circuit 146 that may be applied to the band 154 for electrically coupling the thermoelectric generator modules 102 to a load (not shown). The load may be an electronic device co-located on the wearable band 154, or the load may be separate from the wearable band 154).

The plurality of thermoelectric generator modules 102 may be mounted to the band 154 and electrically connected to one another in series and/or in parallel. In the present disclosure, the combination of the wearable band 154 and the printed circuit 146 may be described as a matrix 138. The matrix 138 may be configured such that the heads 108 of the bottom heat coupling plate 106 of each one of the thermoelectric generator modules 102 are exposed to a heat source 52, and the top heat coupling plate 104 may be exposed to a heat sink 54. For example, the protruding head 108 of the bottom heat coupling plate 106 may be configured to be placed into contact with a heat source 52 such as a wearer's skin (not shown). The protruding head 108 of the top heat coupling plate 104 may be exposed to a heat sink 54 such as ambient air.

The wearable band 154 configuration may be worn by a user and may exploit heat that is constantly rejected from the wearer's skin (not shown) by generating electricity for powering an electronic device. In some examples, the wearable band 154 may be configured be worn around a wearer's wrist, arm, leg, torso, or any other body part. The wearable band 154 may include one or more strain-relief cutouts 156 and or geometrically-shaped cutouts (e.g., semi-circles) located between adjacent pairs of openings 140 to provide increased flexibility for the wearable band 154 for conforming to a contour of a wearer's body. In some examples, one or more of the thermoelectric generator modules 102 may include energy-output capability. For example, one or more of the thermoelectric generator modules 102 may include a thermoelectric foil 10 of which a portion of the thermoelectric legs 26 are electrically isolated from the remaining thermoelectric legs 26 (e.g., see FIG. 37). The electrically-isolated thermoelectric legs 26 may be configured to function as a sensor to provide an indication of the heat flux of the wearer's body as a means to monitor energy expenditure of the wearer (e.g., calories burned) during an activity.

In some examples, the wearable band 154 may include one or more layers (not shown) of high-thermal-resistance material to increase the total thermal resistance of the wearable band 154. The high-thermal-conductivity inner layers (e.g., formed of carbon-fiber material) may be applied to an inner circumference or surface of the wearable band 154. Such high-thermal-conductivity layers may be configured to collect thermal energy from the entire interior surface or portion of the wearable band 154 (e.g., wristband, armband, torso band, leg band, etc.), and funnel the heat into the thermoelectric generator modules 102 and out through heat exchangers (not shown) that may be thermally coupled to one or more of the thermoelectric generator modules 102.

In some examples, the thermoelectric generator modules 102 may include support tabs 192 configured for mounting to the wearable band 154. Each one of the support tabs 192 may include a mounting feature 194 that may be positioned on the module 102 to provide the desired amount of protrusion of the thermoelectric generator module 102 through the opening 140 in the wearable band 154. The support tabs 192 may be placed in contact with a surface of the wearable band 154. In some examples, the exposed portion of the electrical contact clips 130 on the mounting tabs may be aligned with a printed circuit 146 (not shown) that may be applied to the wearable band 154. A plurality of the thermoelectric generator modules 102 may be electrically coupled together by means of circuitry that may be applied to the underside of the wearable band 154. For example, an external clip portion 190 (FIG. 24) of each electrical contact clip 130 may be soldered to a printed circuit 146 of the wearable band 154. It should be noted that the thermoelectric generator modules 102 disclosed herein may be incorporated into any one of a variety of different configurations of wearable thermoelectric generator assemblies, and are not limited to incorporation into a wearable band 154 configuration.

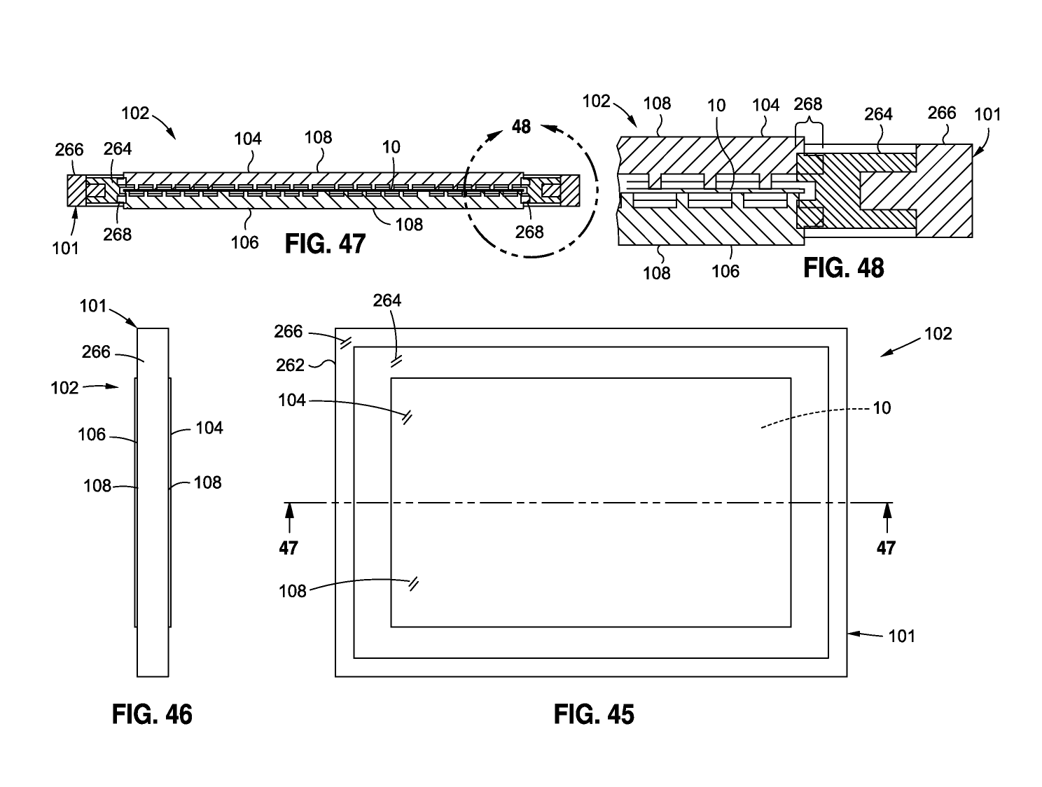

FIG. 45 is a top view of a further embodiment of a thermoelectric generator module 102 wherein the perimeter band 101 is configured as a frame assembly 262 having an inner frame 264 surrounded by an outer frame 266, and wherein the thermoelectric generator module 102 may be assembled without the use of assembly adhesive. The inner frame 264 may be formed of a thermoplastic elastomeric material, and may be sized and configured to circumscribe and surround the perimeter edges of the top and bottom heat coupling plate 104, 106 to encapsulate the thermoelectric foil 10. The outer frame 266 may be formed of a relatively high-strength polymeric material. The outer frame 266 may circumscribe the perimeter of the inner frame 264 and may be formed of a high-strength material providing a relatively high degree of strength for mechanically stabilizing the top and bottom heat coupling plate 104, 106 to protect the thermoelectric foil 10 from excessive compressive, tensile, and/or shear forces that may otherwise compromise the integrity of the thermal coupling and electrical connection between the components of the thermoelectric foil 10 and the top and bottom heat coupling plate 104, 106.

FIG. 46 is a side view of the thermoelectric generator module 102 of FIG. 45. The inner frame 264 and outer frame 266 may be provided in a thickness and geometry such that the head 108 of the top and bottom heat coupling plate 104, 106 protrude above the upper and lower surface of the inner frame 264 and/or outer frame 266. As indicated above, by configuring the inner and outer frame 266 such that the head 108 of the top and bottom heat coupling plate 104, 106 protrudes respectively above and below the upper and lower surface of the inner and outer frame 266, the head 108 of the top and/or bottom heat coupling plate 104, 106 may preferentially be in contact with a heat source or heat flow, instead of the inner frame 264 and outer frame 266. In this regard, the protrusion of the heads 108 above the upper and lower surface of the perimeter band 101 may facilitate heat flow predominantly through the thermoelectric legs and reduce the shunting of heat through the frame assembly 262.

FIG. 47 is a sectional view of the thermoelectric generator module 102 showing the inner frame 264 surrounding the top and bottom heat coupling plate 104, 106, and showing the outer frame 266 surrounding the inner frame 264. In the embodiment shown, the inner perimeter of the inner frame 264 may be sized and configured to provide an interference fit 268 with the perimeter of the top and bottom heat coupling plate 104, 106 during initial assembly. The outer perimeter of the inner frame 264 may have a cross-sectional shape configured to mechanically engage with an inner perimeter of the outer frame 266. For example, FIG. 47 illustrates a U-shaped cross section of an outer perimeter of the inner frame 264 for engaging a complementary T-shaped cross section of an inner perimeter of the outer frame 266. However, the inner and outer frame 264, 266 may be provided with any number of a variety of different cross sectional shapes to facilitate engagement of the inner frame 264 with the outer frame 266.

FIG. 48 is an enlarged sectional view of a side of the thermoelectric generator module 102 of FIG. 45 and illustrating engagement of the inner frame 264 with the edges of the top and bottom heat coupling plate 104, 106. As indicated above, the inner frame 264 may be formed of a thermoplastic elastomer material such as a polyolefin-based material. In some examples, the thermoplastic elastomer material may be provided as commercially-available Santoprene™. The thermoplastic elastomer material may comprise a blend of a thermoplastic resin (e.g., polypropylene, acrylonitrile butadiene styrene or ABS, etc.), and an elastomer (e.g., nitrile, ethylene propylene diene monomer or EPDM rubber, etc.). The thermoplastic elastomer material may be provided in a material composition having a relatively high compressive strength to provide mechanical stability to the thermoelectric generator module 102 and provide sealing and adhesive capability between the inner frame 264 and the top and bottom heat coupling plate 104, 106. In this regard, the thermoplastic elastomer material of the inner frame 264 may preferably have a melt temperature that is below the maximum temperature of the heat coupling plate/thermoelectric foil assembly, and wherein the melt temperature is also preferably significantly higher than the operating temperature range of the thermoelectric generator module 102. By forming the inner frame 264 of a material having a melt temperature below the maximum temperature of the heat coupling plate/thermoelectric foil 10 assembly, the inner frame 264 may be assembled with an interference fit 268 around the heat coupling plate/foil assembly, and then the inner frame may be heated to above its melt temperature causing the inner frame 264 material to flow slightly and form a sealing bond with the side edges and end edges of the top and bottom heat coupling plate 104, 106.

Advantageously, the arrangement of the inner and outer frame 264, 266 shown in FIGS. 45-48 provides a means to assemble a thermoelectric generator module 102 without the use of assembly adhesive to bond the perimeter band 101 to the top and bottom heat coupling plate 104, 106. In some embodiments, the thermoelectric generator module 102 embodiment shown in FIGS. 45 to 48 may include one or more compression blocks (not shown) that may be positioned at spaced locations along the side edges between the inner surfaces of the top and bottom heat coupling plate 104, 106 to increase the compressive strength of the thermoelectric generator module 102 and thereby protect the thermoelectric foil 10 from excessive compressive force. In some examples, compression blocks may be installed between the top and bottom heat coupling plate 104, 106 prior to assembling the inner frame 264 around the top and bottom heat coupling plate/foil assembly. Alternatively, compression blocks may be installed following the heating and bonding of the inner frame 264 to the top and bottom heat coupling plate 104, 106.

As indicated above, the outer frame 266 may be formed of a relatively high-strength polymeric material. In one embodiment, the outer frame 266 may be formed of liquid crystal polymeric material which may glass-filled to allow for molding the outer frame 266 with a high degree of dimensional stability and with minimal distortion. The material of the outer frame 266 may also preferably provide a high degree of strength and mechanical stability to the thermoelectric generator module 102, and may preferably exhibit a high level of resistance to chemical attack. In some examples, the liquid crystal polymeric material for the outer frame 266 may be commercially-available Kevlar™. In another example, the liquid crystal polymeric material for the outer frame 266 may be commercially-available as VECTRA E130i from Celanese Corporation of Irving, Tex. In other examples, the liquid crystal polymer maternal may include reinforcing fibers to increase the compressive strength, tensile strength, and/or shear strength of the outer frame 266.

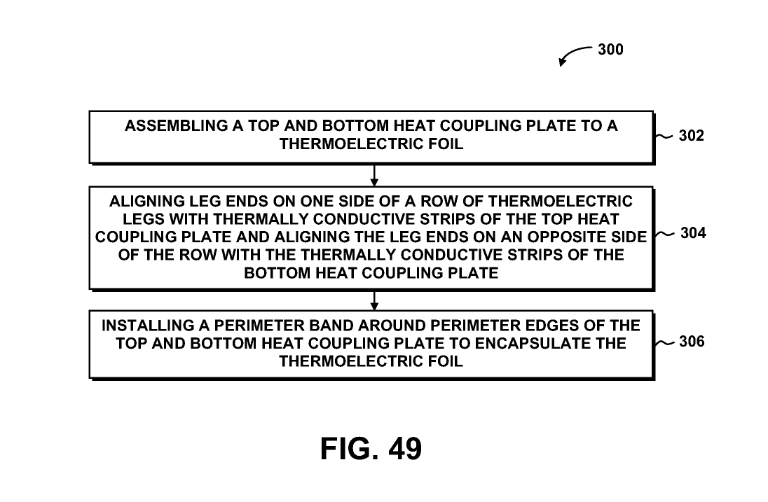

FIG. 49 is a flowchart having one or more operations that may be included in a method 300 of manufacturing a thermoelectric generator module 102. Step 302 of the method may include assembling a top and bottom heat coupling plate 104, 106 to opposite sides of a thermoelectric foil 10. For example, FIG. 25 illustrates the application of a thermally conductive adhesive 119 to the top surfaces of the thermally conductive strips 66 of the bottom heat coupling plate 106. FIG. 26 illustrates the assembly of the thermoelectric foil 10 onto the bottom heat coupling plate 106. FIG. 27 illustrates the assembly of the top heat coupling plate 104 on top of the thermoelectric foil 10.

The method 300 may further include Step 304 of aligning the top and bottom heat coupling plates with the thermoelectric foil 10 during the assembly process. For example, the method may include aligning the leg ends 28 on one side of each row 60 of thermoelectric legs 26 with the thermally conductive strips 66 of the top heat coupling plate 104, and aligning the leg ends 28 on an opposite side of each row 60 with the thermally conductive strips 66 of the bottom heat coupling plate 106. The alignment of the leg ends 28 with the thermally conductive strips 66 on the respective top and bottom heat coupling plates 104, 106 may facilitate the lengthwise flow of heat through the thermoelectric legs 26 when a heat gradient exists across the top and bottom heat coupling plate 104, 106. The lengthwise flow of heat to the thermoelectric legs 26 may result in the generation of electrical current which may flow in series through the thermoelectric legs 26.

Step 306 of the method 300 may include installing a perimeter band 101 around the perimeter edges of the top and bottom heat coupling plate 104, 106 to structurally stabilize the assembly, and to encapsulate the thermoelectric foil 10. In some examples, the step of installing the perimeter band 101 may include assembling a pair of side closeouts 160 respectively to opposite sides of the top and bottom heat coupling plate 104, 106. For example, FIG. 28 illustrates a pair of side closeouts 160 mounted to opposite sides of the assembled top and bottom heat coupling plate 104, 106 and thermoelectric foil 10. The method may further include limiting contact of the inner surface 113 of the top and/or bottom heat coupling plate 106 to contact with one or more shelves 123 locally formed on the inner surfaces of the side closeouts 160. For example, FIG. 24 illustrates an inner surface 113 of the bottom heat coupling plate 106 in contacting relation to a shelf surface 124 on an underside of the shelf 123 of a side closeout 160. In some examples, assembly adhesive 118 may be applied to the spacer portions 182 of the side closeouts 160 for bonding to the side edges of the top and bottom heat coupling plate 104, 106. The assembly adhesive 118 may seal the perimeter of the thermoelectric generator module 102.

The method 300 may further include applying an end barrier 260 (FIG. 28) to each one of the opposing ends of the assembled top and bottom heat coupling plate 104, 106. In some examples, an end barrier 260 (e.g., tape) may extend vertically between the end edges of the top and bottom heat coupling plate 104, 106 as shown in FIG. 28. The method may further include applying assembly adhesive 118 to the spacer portions 182 of the inserts 120 for bonding the inserts 120 to the end edges of the top and bottom heat coupling plate 104, 106. In this regard, the method may include limiting contact of the side closeouts 160 and inserts 120 with the top and bottom heat coupling plate 104, 106 except at the spacer portions 182. By limiting the amount of surface area of contact between the top and bottom heat coupling plates and the side closeouts 160/inserts 120, the potential for shunting of heat flow through the side closeouts 160 and inserts 120 may be reduced.

The method may further include inserting prongs 125 of the inserts 120 into a corresponding set of notches 180 collectively defined by the side closeouts 160 and the recessed portions 110 of the top and bottom heat coupling plate 104, 106. As indicated above, the prongs 125 may overlap the recessed portion 110 of the top and/or bottom heat coupling plate 104, 106, and may be bonded to the side closeouts 160. The process of manufacturing the thermoelectric generator model may be facilitated by using one or more lead frames 196 that may be formed with the side closeouts 160 and/or inserts 120 as shown in FIGS. 38-39. The lead frames 196 may facilitate handling of the side closeouts 160 and inserts 120 during the assembly process, after which the lead frames 196 may be physically separated from the support tabs 192. In some examples, the method may include filling an interior 103 of the thermoelectric generator module 102 with fluid of relatively low thermal conductivity. For example, the thermal gaps 68 (see FIG. 11) between the thermally conductive strips 66 may be filled with gas having relatively low thermal conductivity.

The method may further include electrically connecting the thermoelectric generator module 102 to a load (e.g., an electronic device) or to another thermoelectric generator module 102. For example, the method may include connecting a pair of electrical contact clips 130 to a corresponding pair of metal contacts 76 on opposite ends of a series of the thermoelectric legs 26 of a thermoelectric foil 10. As indicated above, each one of the electrical contact clips 130 may be extended through the perimeter band 101 to an exterior of the thermoelectric generator module 102. In some embodiments, each one of the electrical contact clips 130 may include an external clip portion 190 that may be exposed for connection to a printed circuit 146 or hard wiring. For example, one or more thermoelectric generator modules 102 may be installed through openings 140 formed in a matrix 138 or a band or other wearable thermoelectric generator assembly 100. The wearable thermoelectric generator assembly 100 may include a printed circuit 146, a portion of which may be aligned with the external clip portions 190 of the electrical contact clips 130 of the thermoelectric generator modules 102. In this manner, a plurality of thermoelectric generator modules 102 may be electrically connected in series and/or in parallel.

Additional modifications and improvements of the present disclosure may also be apparent to those of ordinary skill in the art. Thus, the particular combination of parts described and illustrated herein is intended to represent only certain embodiments of the present disclosure, and is not intended to serve as limitations of alternative devices within the spirit and scope of the disclosure.

What is claimed is:

1. A thermoelectric generator module for a wearable thermoelectric generator assembly, comprising:
a top heat coupling plate and a bottom heat coupling plate each having a head formed on an outer surface of the heat coupling plate and thermally conductive strips formed on an inner surface;
at least one thermoelectric foil interposed between the top and bottom heat coupling plate and including a substrate having a plurality of thermoelectric legs formed in at least one row on the substrate and electrically connected in series, opposing leg ends of the thermoelectric legs in each row being aligned with the thermally conductive strips of the respective top and bottom heat coupling plate such that a heat gradient across the top and bottom heat coupling plate causes heat to flow lengthwise through the thermoelectric legs and generating electrical current flowing in series through the thermoelectric legs;
a perimeter band circumscribing perimeter edges of the top and bottom heat coupling plate and encapsulating the thermoelectric foil; and
the head of at least one of the top and bottom heat coupling plate protruding beyond upper and/or lower surfaces of the perimeter band.

2. The thermoelectric generator module of claim 1, wherein the perimeter band includes:
a pair of side closeouts each having an upper surface and a lower surface and being mountable on opposite sides of the top and bottom heat coupling plate;
a pair of inserts each having an upper surface and a lower surface and being mountable on opposite ends of the top and bottom heat coupling plate and interconnectable to opposite ends of the side closeouts; and
the head of at least one of the top and bottom heat coupling plate protruding beyond upper and/or lower surfaces of the side closeouts and inserts.

3. The thermoelectric generator module of claim 2, wherein:
each one of the side closeouts including at least one support tab having a mounting feature located below a height of the upper surface of the side closeout; and
each mounting feature being mountable to a matrix for coupling the thermoelectric generator module to the matrix.

4. The thermoelectric generator module of claim 2, further including:
at least one electrical contact clip extending through the perimeter band and into an interior of the thermoelectric generator module and electrically connecting to an end of a series of the thermoelectric legs.

5. The thermoelectric generator module of claim 2, wherein:
each one of the side closeouts each having upper and lower side flanges respectively forming the upper and lower surfaces of the side closeout; and
the upper and lower side flanges of each side closeout being receivable within recessed portions extending along opposite sides of the respective top and bottom heat coupling plate.

6. The thermoelectric generator module of claim 2, wherein:
each one of the side closeouts including a pair of notches formed in opposing ends of both the upper and lower side flanges;
each one of the inserts including a pair of prongs extending from an inner surface of the insert on opposing ends of both the upper and lower sides of the insert; and
each one of the prongs being receivable within a notch and at least partially overlapping recessed portion of a top and/or bottom heat coupling plate.

7. The thermoelectric generator module of claim 2, wherein:
each one of the side closeouts including at least one shelf protruding from an inner surface of the side closeout, the shelf having a shelf surface configured to contact the inner surface of the top or bottom heat coupling plate for fixing a position of the side closeout relative to the inner surface of the top or bottom heat coupling plate.

8. The thermoelectric the generator module of claim 2, wherein:
each one of the side closeouts having at least one spacer portion protruding from an inner surface of the side closeout and configured to contact a side edge of both the top and bottom heat coupling plate; and
the spacer portions being sized and configured such that when the spacer portions of both of the side closeouts are in contact with the top and bottom heat coupling plate, displacement of the top and bottom heat coupling plate in a lateral direction relative to one another is prevented.

9. The thermoelectric generator module of claim 2, wherein:
each one of the inserts having at least one spacer portion protruding from an inner surface of the side closeout and configured to contact an end edge of both the top and bottom heat coupling plate; and
the spacer portions being sized and configured such that when the spacer portions of both of the inserts are in contact with the top and bottom heat coupling plate, displacement of the top and bottom heat coupling plate in a longitudinal direction relative to one another is prevented.

10. The thermoelectric generator module of claim 1, wherein:
at least one portion of the thermoelectric legs is electrically-isolated from a remaining portion of the thermoelectric legs and electrically coupled to a pair of electrical contact clips.

11. The thermoelectric generator module of claim 1, wherein:
the at least one thermoelectric foil comprises a plurality of thermoelectric foils arranged in side-by-side relation and interposed between the top and bottom heat coupling plate.

12. The thermoelectric generator module of claim 1, wherein:
the perimeter band comprises assembly adhesive applied to the edges of the top and bottom heat coupling plate and hardened forming a seal encapsulating the thermoelectric foil between the top and bottom heat coupling plate.

13. The thermoelectric generator module of claim 1, wherein:
the perimeter band is formed as an outer ring having a unitary structure.

14. The thermoelectric generator module of claim 1, wherein:
the perimeter band is formed as a frame assembly including an inner frame surrounded by an outer frame;
the inner frame formed of a thermoplastic elastomeric material and circumscribing and contacting the perimeter edges of the top and bottom heat coupling plate; and
the outer frame formed of a polymeric material and circumscribing the inner frame.

15. A thermoelectric generator module for a wearable thermoelectric generator assembly, comprising:
a top heat coupling plate and a bottom heat coupling plate each having a head formed an outer surface of the heat coupling plate and having thermally conductive strips formed on an inner surface of the heat coupling plate;
at least one thermoelectric foil interposed between the top and bottom heat coupling plate and including a substrate having a plurality of thermoelectric legs formed in at least one row on the substrate and electrically connected in series, an end of the thermoelectric legs in the row being aligned with the thermally conductive strips of the top heat coupling plate and an opposite end of the thermoelectric legs being aligned with the thermally conductive strips of the bottom heat coupling plate such that a heat gradient across the top and bottom heat coupling plate causes heat to flow lengthwise through the thermoelectric legs and electrical current to flow in series through the thermoelectric legs;
a perimeter band circumscribing the top and bottom heat coupling plate and encapsulating the thermoelectric foil, the perimeter band including:
a pair of side closeouts and a pair of inserts respectively mounted on opposing sides and ends of the top and bottom heat coupling plate; and
a head of at least one of the top and bottom heat coupling plate protruding beyond upper and/or lower surfaces of the side closeouts and inserts.

16. A method of manufacturing a wearable thermoelectric generator assembly, comprising the steps of:
assembling a top and bottom heat coupling plate to opposite sides of a thermoelectric foil including a substrate having a plurality of thermoelectric legs each having opposing leg ends and formed in at least one row on the substrate and electrically connected in series;
aligning leg ends on one side of a row of thermoelectric legs with thermally conductive strips of the top heat coupling plate and aligning the leg ends on an opposite side of the row with the thermally conductive strips of the bottom heat coupling plate; and
installing a perimeter band around perimeter edges of the top and bottom heat coupling plate to encapsulate the thermoelectric foil, a head of at least one of the top and bottom heat coupling plate protruding beyond upper and/or lower surfaces of the perimeter band.

17. The method of claim 16, wherein the step of installing the perimeter band comprises:
assembling a pair of side closeouts respectively to opposite sides of the top and bottom heat coupling plate;
assembling a pair of inserts respectively to opposite ends of the top and bottom heat coupling plate; and
a head of at least one of the top and bottom heat coupling plate protruding beyond an upper and/or lower surface of the side closeouts and inserts.

18. The method of claim 17, wherein the step of assembling the pair of inserts to the top and bottom heat coupling plate includes:
inserting a set of prongs extending from an inner surface of each one of the inserts into a corresponding set of notches collectively defined by the side closeouts and the top and bottom heat coupling plate; and
overlapping, using the prongs, recessed portions of the top and/or bottom heat coupling plate.

19. The method of claim 17, further comprising:
limiting contact of an inner surface of the top and/or bottom heat coupling plate to contact with one or more shelves protruding from inner surfaces of the perimeter band.

20. The method of claim 16, further comprising:
applying assembly adhesive to perimeter edges of the top and bottom heat coupling plate; and
hardening the assembly adhesive forming a seal encapsulating the thermoelectric foil between the top and bottom heat coupling plate.

21. The method of claim 16, further comprising:
forming the perimeter band as an outer ring having a unitary structure.
